(19) United States
(12) Patent Application Publication
(10) Pub. No.: US 2025/0261370 A1
(43) Pub. Date: Aug. 14, 2025

(54) SEMICONDUCTOR DEVICE AND ELECTRONIC SYSTEM INCLUDING THE SAME

(71) Applicant: Samsung Electronics Co., Ltd., Suwon-si (KR)

(72) Inventors: Jaeshin LEE, Suwon-si (KR); Jiyeon KIM, Suwon-si (KR); SUBIN SHIN, Suwon-si (KR); Seuongjae YU, Suwon-si (KR); JUNGWOONG LEE, Suwon-si (KR); DA WOON JEONG, Suwon-si (KR); JAEYONG CHOI, Suwon-si (KR)

(21) Appl. No.: 18/886,047

(22) Filed: Sep. 16, 2024

(30) Foreign Application Priority Data
Feb. 13, 2024 (KR) 10-2024-0020616

(51) Int. Cl. H10B 43/27; G11C 16/04; H01L 25/065; H10B 41/10; H10B 41/27; H10B 41/35; H10B 43/10; H10B 43/35; H10B 80/00

(52) U.S. Cl. CPC H10B 43/27; G11C 16/0483; H01L 25/0652; H10B 41/10; H10B 41/27; H10B 41/35; H10B 43/10; H10B 43/35; H10B 80/00; H01L 2225/06524

(57) ABSTRACT

A semiconductor device may include a semiconductor substrate, an electrode structure including electrodes and insulating layers, which are alternately stacked on the semiconductor substrate in a vertical direction, middle separation structures that penetrate an upper portion of the electrode structure, and horizontally separate portions of the electrodes located in the upper portion from each other, vertical structures penetrating through the electrode structure, and dummy vertical structures penetrating through the electrode structure and vertically overlapped with the middle separation structures. Each of the dummy vertical structures may include a dummy gapfill insulating pattern, a dummy vertical semiconductor pattern enclosing a side surface of the dummy gapfill insulating pattern, and a dummy data storage pattern enclosing a side surface of the dummy vertical semiconductor pattern. The uppermost portion of the dummy vertical semiconductor pattern may be in contact with a side surface of the dummy data storage pattern.

### CROSS-REFERENCE TO RELATED APPLICATIONS

This U.S. non-provisional patent application claims priority under 35 U.S.C. § 119 to Korean Patent Application No. 10-2024-0020616, filed on Feb. 13, 2024, in the Korean Intellectual Property Office, the entire contents of which are hereby incorporated by reference.

### BACKGROUND OF THE INVENTION

The present disclosure relates to a semiconductor device and an electronic system including the same.

A semiconductor device capable of storing a large amount of data is required for data storage of an electronic system. Accordingly, many studies are being conducted to increase the data storage capacity of the semiconductor device. For example, semiconductor devices, in which memory cells are three-dimensionally arranged, are being suggested.

### SUMMARY

An embodiment of the inventive concept provides a semiconductor device with improved reliability and an increased integration density.

An embodiment of the inventive concept provides an electronic system including a semiconductor device.

An embodiment of the inventive concept provides a semiconductor device that can be more easily fabricated.

According to an embodiment of the inventive concept, a semiconductor device may include a semiconductor substrate, an electrode structure including electrodes and insulating layers, which are stacked on the semiconductor substrate in a vertical direction and that alternate between an electrode and an insulating layer in the vertical direction, middle separation structures that penetrate an upper portion of the electrode structure, and horizontally separate portions of the electrodes located in the upper portion from each other, vertical structures penetrating through the electrode structure, and dummy vertical structures penetrating through the electrode structure and vertically overlapped with the middle separation structures. Each of the dummy vertical structures may include a dummy gapfill insulating pattern, a dummy vertical semiconductor pattern enclosing a side surface of the dummy gapfill insulating pattern, and a dummy data storage pattern enclosing a side surface of the dummy vertical semiconductor pattern. The uppermost portion of the dummy vertical semiconductor pattern may be in contact with a side surface of the dummy data storage pattern and the uppermost portion of the dummy vertical semiconductor pattern is a portion of the dummy vertical semiconductor pattern located at a level higher than the uppermost portion of the dummy gapfill insulating pattern.

According to an embodiment of the inventive concept, a semiconductor device may include a semiconductor substrate, an electrode structure including electrodes and insulating layers stacked on the semiconductor substrate in a vertical direction and that alternate between an electrode and an insulating layer in the vertical direction, middle separation structures that penetrate through an upper portion of the electrode structure to horizontally separate portion of the electrodes located in the upper portion from each other, vertical structures penetrating through the electrode structure, each of the vertical structures including a gapfill insulating pattern, a vertical semiconductor pattern enclosing a side surface of the gapfill insulating pattern, and a data storage pattern enclosing a side surface of the vertical semiconductor pattern, and dummy vertical structures penetrating through the electrode structure and vertically overlapped with the middle separation structures. Each of the dummy vertical structures may include a dummy gapfill insulating pattern, a dummy vertical semiconductor pattern enclosing a side surface of the dummy gapfill insulating pattern, and a dummy data storage pattern enclosing a side surface of the dummy vertical semiconductor pattern. Each of the middle separation structures may have a first seam vertically overlapped with the dummy gapfill insulating pattern, and each of the vertical structures may have a second seam formed in the gapfill insulating pattern. A width of the first seam may be larger than a width of the second seam.

According to an embodiment of the inventive concept, an electronic system may include a semiconductor device including a semiconductor substrate, an electrode structure including electrodes and insulating layers substrate in a vertical direction and that alternate between an electrode and an insulating layer in the vertical direction, middle separation structures that penetrate through an upper portion of the electrode structure to separate portion of the electrodes in the upper portion from each other, vertical structures penetrating through the electrode structure, and dummy vertical structures penetrating through the electrode structure and vertically overlapped with the middle separation structures, and a controller electrically connected to the semiconductor device through an input/output pad and configured to control the semiconductor device. Each of the dummy vertical structures may include a dummy gapfill insulating pattern, a dummy vertical semiconductor pattern enclosing a side surface of the dummy gapfill insulating pattern, and a dummy data storage pattern enclosing a side surface of the dummy vertical semiconductor pattern. The uppermost portion of the dummy vertical semiconductor pattern may be in contact with a side surface of the dummy data storage pattern and the uppermost portion of the dummy vertical semiconductor pattern is a portion that located at a level higher than the uppermost portion of the dummy gapfill insulating pattern.

### BRIEF DESCRIPTION OF THE DRAWINGS

FIG. 1 is a diagram schematically illustrating an electronic system including a semiconductor device according to an embodiment of the inventive concept.

FIG. 2 is a perspective view schematically illustrating an electronic system including a semiconductor device according to an embodiment of the inventive concept.

FIGS. 3 and 4 are sectional views schematically illustrating semiconductor packages according to some embodiments of the inventive concept.

FIG. 5 is a plan view illustrating a semiconductor device according to an embodiment of the inventive concept.

FIGS. 6A and 6B are sectional views, which are respectively taken along lines I-I′ and II-II′ of FIG. 5 to illustrate a semiconductor device according to an embodiment of the inventive concept.

FIG. 7 is an enlarged sectional view illustrating a portion ‘Q1’ of FIG. 6B.

FIG. 8 is an enlarged plan view illustrating a portion ‘P’ of FIG. 5.

FIGS. 9A, 9B, 9C, and 9D are sectional views, which are respectively taken along lines A-A′, B-B′, C-C′, and D-D′ of FIG. 8 to illustrate a semiconductor device according to an embodiment of the inventive concept.

FIG. 10A is an enlarged sectional view illustrating a portion ‘Q2’ of FIG. 9B.

FIG. 10B is an enlarged sectional view illustrating a portion ‘Q3’ of FIG. 9C.

FIG. 11 is a sectional view illustrating a semiconductor device according to an embodiment of the inventive concept.

FIGS. 12, 13A, 13B, 13C, 14, 15, 16A, 16B, 16C, 17, 18A, 18B to 18C are diagrams illustrating a method of fabricating a semiconductor device according to an embodiment of the inventive concept in which FIGS. 12 and 15 are plan views of the semiconductor device, and FIGS. 13A to 14 and 16A to 18C are sectional or enlarged views of the semiconductor device.

### DETAILED DESCRIPTION

Example embodiments of the inventive concepts will now be described more fully with reference to the accompanying drawings, in which example embodiments are shown. The invention may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such detail. The language of the claims should be referenced in determining the requirements of the invention.

It will be understood that when an element is referred to as being “connected” or

“coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, items described as being “electrically connected” are configured such that an electrical signal can be passed from one item to the other. Therefore, a passive electrically conductive component (e.g., a wire, pad, internal electrical line, etc.) physically connected to a passive electrically insulative component (e.g., a prepreg layer of a printed circuit board, an electrically insulative adhesive connecting two devices, an electrically insulative underfill or mold layer, etc.) is not electrically connected to that component. Moreover, items that are “directly electrically connected,” to each other are electrically connected through one or more passive elements, such as, for example, wires, pads, internal electrical lines, through vias, etc. As such, directly electrically connected components do not include components electrically connected through active elements, such as transistors or diodes. Directly electrically connected elements may be directly physically connected and directly electrically connected.

Terms such as “same,” “equal,” “planar,” “coplanar,” “parallel,” and “perpendicular,” as used herein encompass identicality or near identicality including variations that may occur resulting from conventional manufacturing processes. The term “substantially” may be used herein to emphasize this meaning, unless the context or other statements indicate otherwise.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

As used herein, the term “dummy” is used to refer to a component that has the same or similar structure and shape as other non-dummy components having the same name, but the “dummy” component is inactive and/or does not have the same function as the non-dummy components having the same name. A “dummy” component may be included for symmetry, structural reinforcement, or other reasons that may be unrelated to the function of the non- dummy components having the same name. In some instances, a “dummy” component may be electrically floated, or may be connected to various voltage sources but otherwise not provide the same functionality of the non-dummy component of the same name.

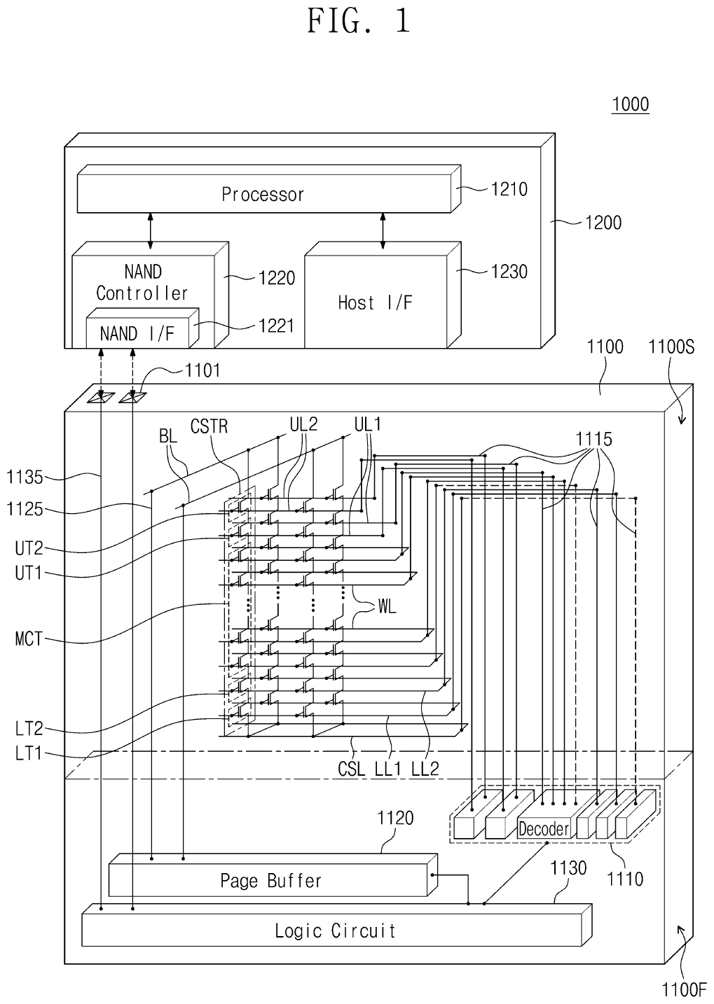

FIG. 1 is a diagram schematically illustrating an electronic system including a semiconductor device according to an embodiment of the inventive concept.

Referring to FIG. 1, an electronic system 1000 according to an embodiment of the inventive concept may include a semiconductor device 1100 and a controller 1200, which is electrically connected to the semiconductor device 1100. The electronic system 1000 may be a storage device, which includes one or more semiconductor devices 1100, or an electronic device including the storage device. For example, the electronic system 1000 may be a solid state drive (SSD) device, a universal serial bus (USB), a computing system, a medical system, or a communication system, in which at least one semiconductor device 1100 is provided.

The semiconductor device 1100 may be a nonvolatile memory device (e.g., a NAND FLASH memory device). The semiconductor device 1100 may include a first structure 1100F and a second structure 1100S on the first structure 1100F. In an embodiment, the first structure 1100F may be disposed near the second structure 1100S. The first structure 1100F may be a peripheral circuit structure, which includes a decoder circuit 1110, a page buffer 1120, and a logic circuit 1130. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may be variously changed, according to embodiments.

In an embodiment, the upper transistors UT1 and UT2 may include at least one string selection transistor, and the lower transistors LT1 and LT2 may include at least one ground selection transistor. The gate lower lines LL1 and LL2 may be used as gate electrodes of the lower transistors LT1 and LT2, respectively. The word lines WL may be used as gate electrodes of the memory cell transistors MCT, and the gate upper lines UL1 and UL2 may be used as gate electrodes of the upper transistors UT1 and UT2, respectively.

In an embodiment, the lower transistors LT1 and LT2 may include a lower erase control transistor LT1 and a ground selection transistor LT2, which are connected in series. The upper transistors UT1 and UT2 may include a string selection transistor UT1 and an upper erase control transistor UT2, which are connected in series. At least one of the lower and upper erase control transistors LT1 and UT1 may be used to perform an erase operation of erasing data in the memory cell transistors MCT using a gate-induced drain leakage (GIDL) phenomenon.

The common source line CSL, the first and second gate lower lines LL1 and LL2, the word lines WL, and the first and second gate upper lines UL1 and UL2 may be electrically connected to the decoder circuit 1110 through first connection lines 1115, which are extended from the first structure 1100F to the second structure 1100S. The bit lines BL may be electrically connected to the page buffer 1120 through second connection lines 1125, which are extended from the first structure 1100F to the second structure 1100S.

In the first structure 1100F, the decoder circuit 1110 and the page buffer 1120 may be configured to perform a control operation on at least one transistor that is selected from the memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output connection line 1135, which is provided in the first structure 1100F and is extended into the second structure 1100S.

The controller 1200 may include a processor 1210, a NAND controller 1220, and a host interface 1230. In an embodiment, the electronic system 1000 may include a plurality of semiconductor devices 1100, and in this case, the controller 1200 may control the semiconductor devices 1100.

The processor 1210 may control overall operations of the electronic system 1000 including the controller 1200. The processor 1210 may be operated based on a specific firmware and may control the NAND controller 1220 to access the semiconductor device 1100. The NAND controller 1220 may include a NAND interface 1221, which is used to communicate with the semiconductor device 1100. The NAND interface 1221 may be used to transmit and receive control commands for controlling the semiconductor device 1100 and data to be written in or read from the memory cell transistors MCT of the semiconductor device 1100. The host interface 1230 may be configured to allow for communication between the electronic system 1000 and an external host. If a control command is received from an external host through the host interface 1230, the processor 1210 may control the semiconductor device 1100 in response to the control command.

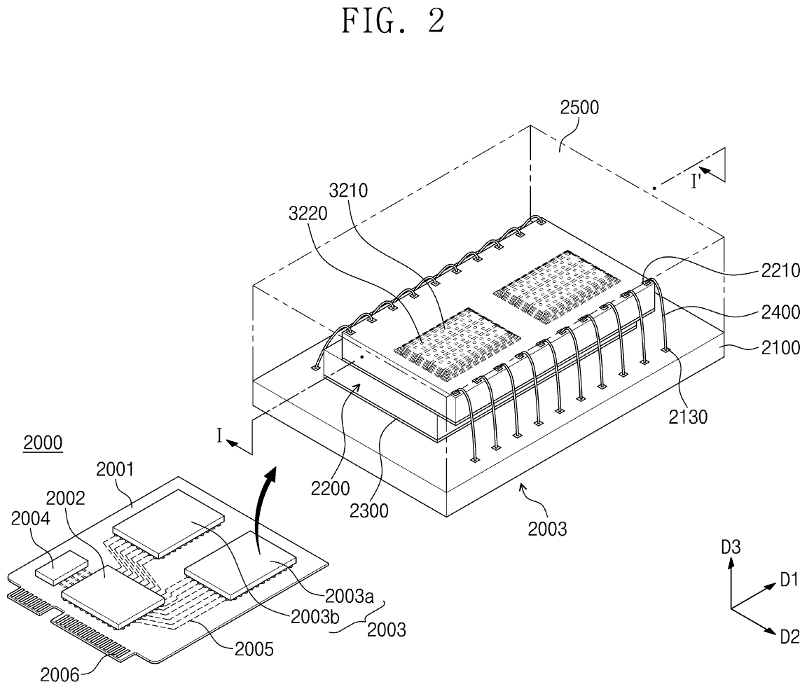

FIG. 2 is a perspective view schematically illustrating an electronic system including a semiconductor device according to an embodiment of the inventive concept.

Referring to FIG. 2, an electronic system 2000 according to an embodiment of the inventive concept may include a main substrate 2001 and a controller 2002, at least one semiconductor package 2003, and a DRAM 2004, which are mounted on the main substrate 2001. The semiconductor package 2003 and the DRAM 2004 may be connected to the controller 2002 through interconnection patterns 2005, which are formed in the main substrate 2001.

The main substrate 2001 may include a connector 2006, which includes a plurality of pins coupled to an external host. In the connector 2006, the number and arrangement of the pins may depend on a communication interface between the electronic system 2000 and the external host. In an embodiment, the electronic system 2000 may communicate with the external host, in accordance with one of interfaces, such as universal serial bus (USB), peripheral component interconnect express (PCI-Express), serial advanced technology attachment (SATA), universal flash storage (UFS) M-Phy, or the like. In an embodiment, the electronic system 2000 may be driven by electrical power, which is supplied from the external host through the connector 2006. The electronic system 2000 may further include a power management integrated circuit (PMIC) that supplies electric power, which is supplied from the external host to the controller 2002 and the semiconductor package 2003.

The controller 2002 may be configured to control a writing or reading operation on the semiconductor package 2003 and to improve an operation speed of the electronic system 2000.

The DRAM 2004 may be a buffer memory that is configured to relieve technical difficulties caused by a difference in speed between the semiconductor package 2003, which serves as a data storage device, and an external host. In an embodiment, the DRAM 2004 in the electronic system 2000 may serve as a cache memory and may be used as a storage space, which is used to temporarily store data during a control operation on the semiconductor package 2003. In the case where the electronic system 2000 includes the DRAM 2004, the controller 2002 may further include a DRAM controller for controlling the DRAM 2004, in addition to a NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200 on the package substrate 2100, adhesive layers 2300 respectively disposed on bottom surfaces of the semiconductor chips 2200, a connection structure 2400 electrically connecting the semiconductor chips 2200 to the package substrate 2100, and a molding layer 2500 disposed on the package substrate 2100 to cover the semiconductor chips 2200 and the connection structure 2400.

The package substrate 2100 may be a printed circuit board including upper pads 2130. Each of the semiconductor chips 2200 may include an input/output pad 2210. The input/output pad 2210 may correspond to the input/output pad 1101 of FIG. 1. Each of the semiconductor chips 2200 may include electrode structures 3210 and vertical structures 3220. Each of the semiconductor chips 2200 may include a semiconductor device, which will be described below, according to an embodiment of the inventive concept.

In an embodiment, the connection structure 2400 may include a bonding wire electrically connecting the input/output pad 2210 to the upper pads 2130. Thus, in each of the first and second semiconductor packages 2003a and 2003b, the semiconductor chips 2200 may be electrically connected to each other in a bonding wire manner and may be electrically connected to the upper pads 2130 of the package substrate 2100. In an embodiment, the semiconductor chips 2200 in each of the first and second semiconductor packages 2003a and 2003b may be electrically connected to each other by a connection structure including through silicon vias (TSVs), not by the connection structure 2400 provided in the form of bonding wires.

In an embodiment, the controller 2002 and the semiconductor chips 2200 may be included in a single package. In an embodiment, the controller 2002 and the semiconductor chips 2200 may be mounted on a separate interposer substrate, which is prepared regardless of the main substrate 2001, and may be connected to each other through interconnection lines, which are provided in the interposer substrate.

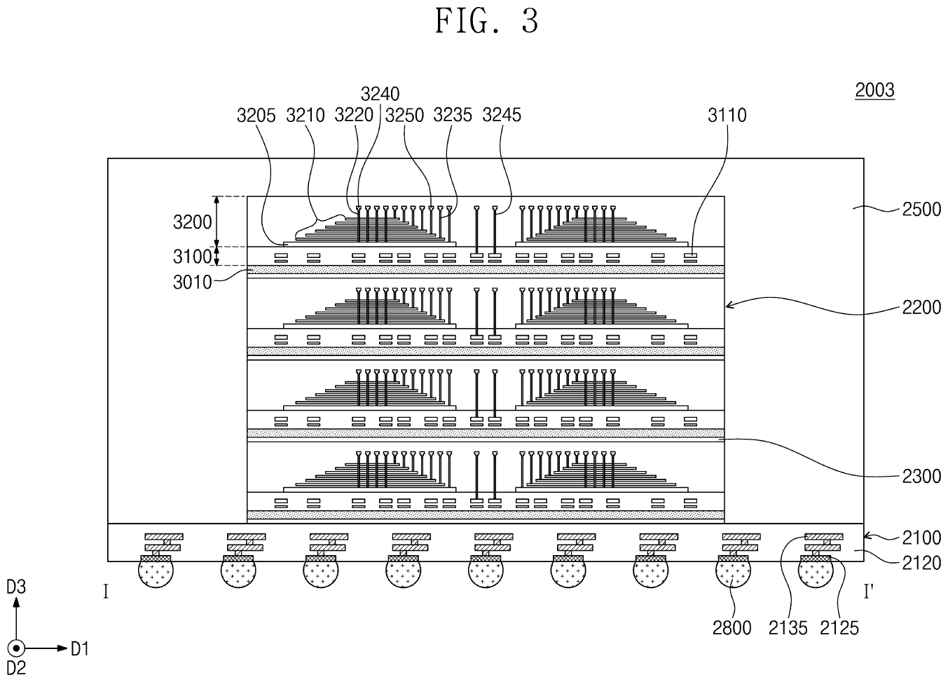

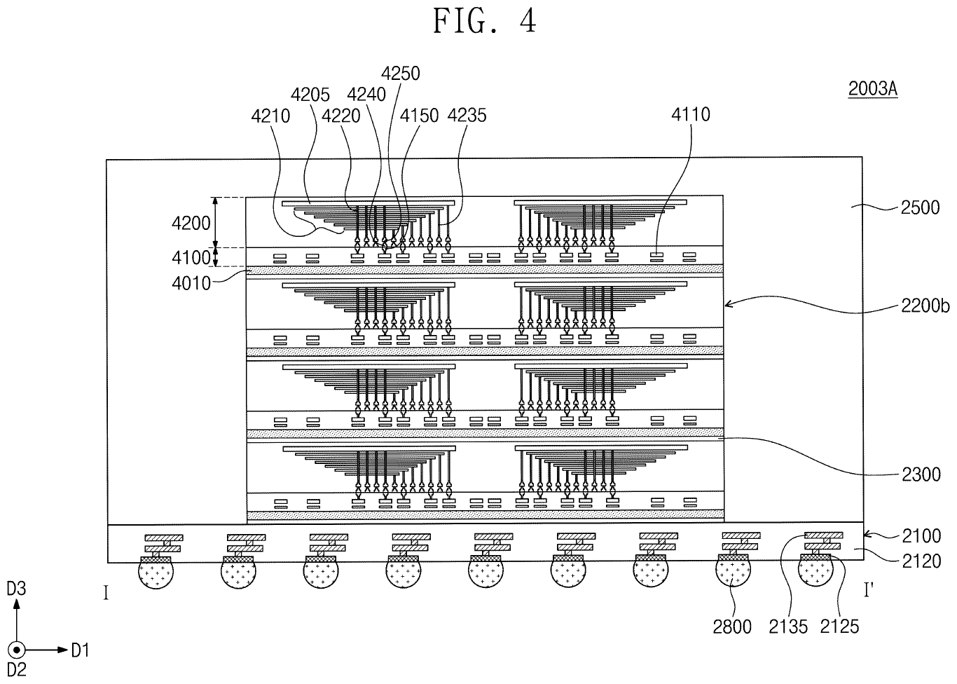

FIGS. 3 and 4 are sectional views schematically illustrating semiconductor packages according to some embodiments of the inventive concept. FIGS. 3 and 4 are sectional views, which are taken along line I-I′ of FIG. 2 to illustrate two different examples of the semiconductor package 2003 of FIG. 2.

Referring to FIG. 3, in the semiconductor package 2003, the package substrate 2100 may be a printed circuit board. The package substrate 2100 may include a package substrate body portion 2120, the package upper pads 2130 (e.g., of FIG. 2), which are disposed on a top surface of the package substrate body portion 2120, lower pads 2125, which are disposed on or exposed through a bottom surface of the package substrate body portion 2120, and internal lines 2135, which are provided in the package substrate body portion 2120 to electrically connect the package upper pads 2130 to the lower pads 2125. The upper pads 2130 may be electrically connected to the connection structures 2400. The lower pads 2125 may be connected to the interconnection patterns 2005 of the main substrate 2001 of the electronic system 2000 of FIG. 2 through conductive connecting portions 2800.

Each of the semiconductor chips 2200 may include a semiconductor substrate 3010 and first and second structures 3100 and 3200, which are sequentially stacked on the semiconductor substrate 3010. The first structure 3100 may include a peripheral circuit region, in which peripheral lines 3110 are provided. The second structure 3200 may include a source structure 3205, an electrode structure 3210 on the source structure 3205, vertical structures 3220 and separation structures penetrating the electrode structure 3210, bit lines 3240 electrically connected to the vertical structures 3220, and cell contact plugs 3235 electrically connected to the word lines WL (e.g., of FIG. 1) of the electrode structure 3210. Each of the first and second structures 3100 and 3200 and the semiconductor chips 2200 may further include a metal structure to be described below.

Each of the semiconductor chips 2200 may include penetration lines 3245, which are electrically connected to the peripheral lines 3110 of the first structure 3100 and are extended into the second structure 3200. The penetration line 3245 may be disposed outside the electrode structure 3210, and in an embodiment, the penetration line 3245 may be provided to further penetrate the electrode structure 3210. Each of the semiconductor chips 2200 may further include the input/output pad 2210 (e.g., of FIG. 2), which is electrically connected to the peripheral line 3110 of the first structure 3100.

Referring to FIG. 4, in a semiconductor package 2003A, each of semiconductor chips 2200a may include a semiconductor substrate 4010, a first structure 4100 on the semiconductor substrate 4010, and a second structure 4200, which is provided on the first structure 4100 and is bonded with the first structure 4100 in a wafer bonding manner.

The first structure 4100 may include a peripheral circuit region, in which a peripheral line 4110 and first junction structures 4150 are provided. The second structure 4200 may include a source structure 4205, an electrode structure 4210 between the first structure 4100 and the source structure 4205, vertical structures 4220 and a separation structure penetrating the electrode structure 4210, and second junction structures 4250, which are electrically and respectively connected to the vertical structures 4220 and the word lines WL (e.g., see FIG. 1) of the electrode structure 4210. For example, the second junction structures 4250 may be electrically and respectively connected to the vertical structures 4220 and the word lines WL (e.g., of FIG. 1) through bit lines 4240, which are electrically connected to the vertical structures 4220, and cell contact plugs 4235, which are electrically connected to the word lines WL (e.g., of FIG. 1). The first junction structures 4150 of the first structure 4100 and the second junction structures 4250 of the second structure 4200 may be bonded to each other and may be in contact with each other. The bonded portions of the first and second junction structures 4150 and 4250 may be formed of or include, for example, copper (Cu).

Each of the first and second structures 4100 and 4200 and each of the semiconductor chips 2200a may further include a metal structure in embodiments to be described below. Each of the semiconductor chips 2200a may further include the input/output pad 2210 (e.g., see FIG. 2), which is electrically connected to the peripheral lines 4110 of the first structure 4100.

The semiconductor chips 2200 of FIG. 3 or the semiconductor chips 2200a of FIG. 4 may be electrically connected to each other by the connection structures 2400, which are provided in the form of bonding wires. However, in an embodiment, semiconductor chips, which are provided in the same semiconductor package as the semiconductor chips 2200 or 2200a of FIG. 3 or 4, may be electrically connected to each other by a connection structure including through silicon vias (TSVs).

The first structure 3100 or 4100 of FIG. 3 or 4 may correspond to a peripheral circuit structure in an embodiment to be described below, and the second structure 3200 or 4200 of FIG. 3 or 4 may correspond to a cell array structure in an embodiment to be described below.

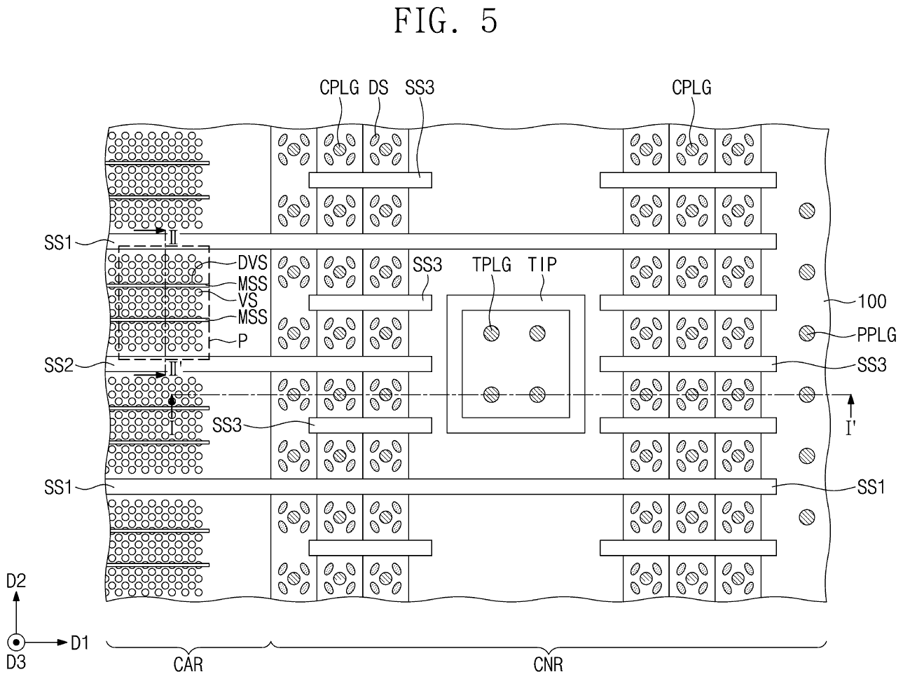

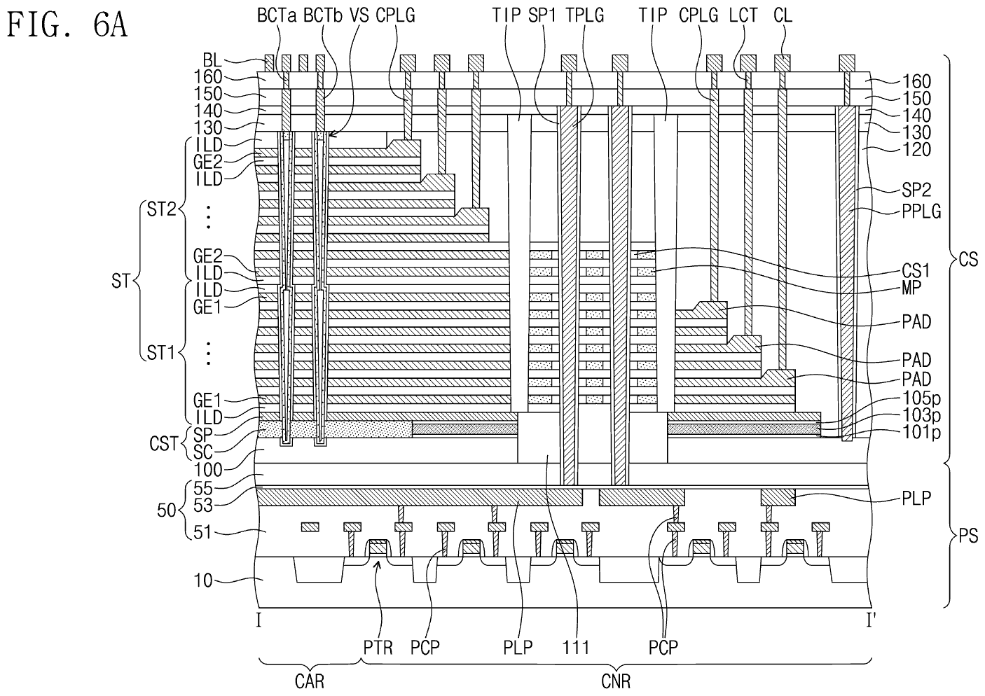

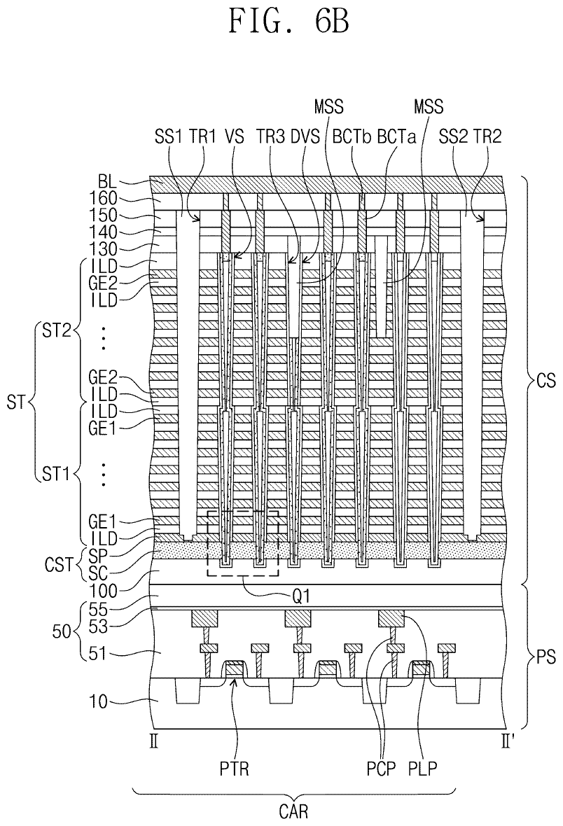

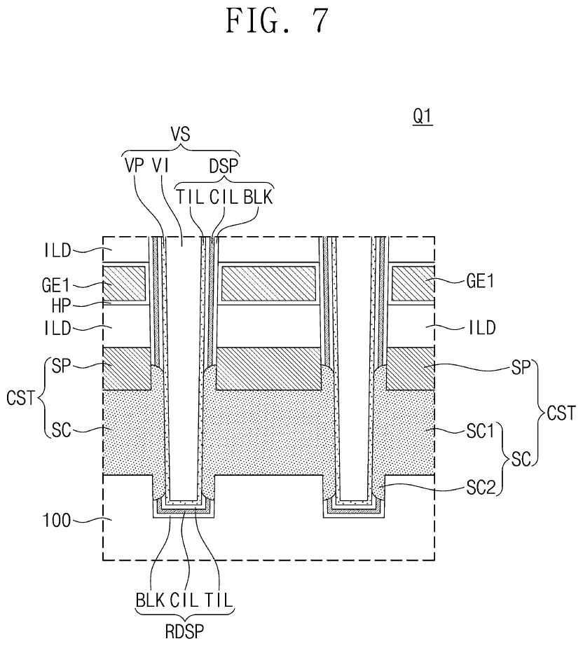

FIG. 5 is a plan view illustrating a semiconductor device according to an embodiment of the inventive concept. FIGS. 6A and 6B are sectional views, which are respectively taken along lines I-I′ and II-II′ of FIG. 5 to illustrate a semiconductor device according to an embodiment of the inventive concept. FIG. 7 is an enlarged sectional view illustrating a portion ‘Q1’ of FIG. 6B.

Referring to FIGS. 5, 6A, and 6B, a semiconductor device according to an embodiment of the inventive concept may include a peripheral circuit structure PS and a cell array structure CS on the peripheral circuit structure PS.

The peripheral circuit structure PS may include peripheral circuits PTR, which are integrated on a semiconductor substrate 10, and a lower insulating layer 50, which covers the peripheral circuits PTR. In an embodiment, the semiconductor substrate 10 may be a silicon wafer. The semiconductor substrate 10 may include a cell array region CAR and a connection region CNR.

The peripheral circuits PTR may include row and column decoders, a page buffer, a control circuit, and so forth. In detail, the peripheral circuits PTR may include NMOS and PMOS transistors. Peripheral circuit lines may be electrically connected to the peripheral circuits PTR through peripheral contact plugs PCP.

The lower insulating layer 50 may be provided on the semiconductor substrate 10. The lower insulating layer 50 may be provided on the semiconductor substrate 10 to cover the peripheral circuits PTR, the peripheral contact plugs PCP, and the peripheral circuit lines PLP. The peripheral contact plugs PCP and the peripheral circuit lines PLP may be electrically connected to the peripheral circuits PTR.

The lower insulating layer 50 may include a plurality of vertically-stacked insulating layers. For example, the lower insulating layer 50 may include a silicon oxide layer, a silicon nitride layer, a silicon oxynitride layer, and/or a low-k dielectric layer. As an example, the lower insulating layer 50 may include a first lower insulating layer 51, a second lower insulating layer 55, and an etch stop layer 53 between the first and second lower insulating layers 51 and 55. The etch stop layer 53 may be formed of or include an insulating material, which is different from the first and second lower insulating layers 51 and 55, and may cover top surfaces of the uppermost ones of the peripheral circuit lines PLP.

The cell array structure CS may be disposed on the lower insulating layer 50. The cell array structure CS may include a semiconductor layer 100, a source structure CST, an electrode structure ST, vertical structures VS, dummy vertical structures DVS, cell contact plugs CPLG, penetration contact plugs TPLG, bit lines BL, and conductive lines CL.

In an embodiment, the memory cell strings CSTR (e.g., of FIG. 1) may be integrated on the semiconductor layer 100. The electrode structure ST and the vertical structures VS may constitute the memory cell strings CSTR of FIG. 1. The vertical structures 3220 may include one or more memory cells.

The dummy vertical structures DVS may include one or more dummy memory cells. The dummy memory cells may be identical to normal memory cells of the vertical structures VS that are connected to word lines and bit lines. The dummy memory cells may have the same or a substantially similar structure as the memory cells of the VS, but may not have any “data” stored to or read from the dummy memory cells by a device external to the semiconductor memory chip. For example, a dummy memory cell may be electrically connected to a word line in the same manner as a normal memory cell but may not have any connection to a bit line to transmit data therebetween as with normal memory cells. The dummy memory cells may be formed as transistors, e.g., as dummy memory cell transistors having the structure of normal memory cell transistors in the vertical structure VS. The dummy memory cell transistors of a dummy vertical structure VS may be connected in series to form a NAND circuit, e.g., forming a dummy NAND string. The NAND string may be a stump circuit with one end of the dummy NAND string disconnected (i.e., not connected to another wire or circuit).

In more detail, the semiconductor layer 100 may be disposed on a top surface of the lower insulating layer 50. The semiconductor layer 100 may be formed of or include at least one of semiconductor, insulating, or conductive materials. The semiconductor layer 100 may be formed of or include a doped semiconductor material of a first conductivity type (e.g., n-type) and/or an undoped or intrinsic semiconductor material. The semiconductor layer 100 may have one of polycrystalline, amorphous, and single-crystalline structures.

The source structure CST may be disposed between the semiconductor layer 100 and the electrode structure ST. The source structure CST may be parallel to a top surface of the semiconductor layer 100 and may be extended from the cell array region CAR in a first direction D1 to be parallel to the electrode structure ST.

The source structure CST may include a source conductive pattern SC and a support conductive pattern SP on the source conductive pattern SC. The source conductive pattern SC may be disposed in the cell array region CAR and between the semiconductor layer 100 and the electrode structure ST. The source conductive pattern SC may be formed of or include a semiconductor material that is doped with dopants (e.g., phosphorus (P) or arsenic (As)) to have a first conductivity type. For example, the source conductive pattern SC may be formed of a poly-silicon layer that is doped with n-type dopants.

In an embodiment, dummy insulating patterns 101p, 103p, and 105p may be disposed in the connection region CNR and between the semiconductor layer 100 and the electrode structure ST. The dummy insulating patterns 101p, 103p, and 105p may be located at substantially the same level as the source conductive pattern SC.

The dummy insulating patterns 101p, 103p, and 105p may include first, second, and third insulating patterns 101p, 103p, and 105p, which are sequentially stacked. The second insulating pattern 103p may include an insulating material different from the first and third insulating patterns 101p and 105p. The second insulating pattern 103p may be thicker than the first and third insulating patterns 101p and 105p. The first, second, and third insulating patterns 101p, 103p, and 105p may be formed of or include at least one of silicon oxide, silicon nitride, silicon oxynitride, silicon carbide, or silicon germanium.

The support conductive pattern SP may cover a top surface of the source conductive pattern SC in the cell array region CAR and may cover top surfaces of the dummy insulating patterns 101p, 103p, and 105p in the connection region CNR. The support conductive pattern SP may be formed of or include a doped semiconductor material of the first conductivity type (e.g., n-type) and/or an undoped or intrinsic semiconductor material.

A penetration insulating pattern 111 may be provided in the connection region CNR to penetrate the source structure CST and the semiconductor layer 100. The penetration insulating pattern 111 may be in contact with the lower insulating layer 50 and may have a top surface that is substantially coplanar with the top surface of the source structure CST.

The electrode structure ST may be disposed on the source structure CST. The electrode structure ST may be extended from the cell array region CAR to the connection region CNR in the first direction D1 and may have a stepwise structure on the connection region CNR.

The electrode structure ST may include electrodes GE1 and GE2 and insulating layers ILD1 and ILD2, which are alternately stacked in a third direction D3 (i.e., a vertical direction), and here, the third direction D3 may be perpendicular to first and second directions D1 and D2 crossing each other. The electrodes GE1 and GE2 may be formed of or include at least one of doped semiconductor materials (e.g., doped silicon and so forth), metals (e.g., tungsten, copper, aluminum, and so forth), conductive metal nitrides (e.g., titanium nitride, tantalum nitride, and so forth), or transition metals (e.g., titanium, tantalum, and so forth). Each of the insulating layers ILD1 and ILD2 may include a silicon oxide layer and/or a low-k dielectric layer. In an embodiment, the semiconductor device may be a vertical NAND FLASH memory device, and in this case, the electrodes GE1 and GE2 of the electrode structure ST may be used as the gate lower lines LL1 and LL2, the word lines WL, and the gate upper lines UL1 and UL2 described with reference to FIG. 1.

In an embodiment, the electrode structure ST may include a first electrode structure ST1 and a second electrode structure ST2 on the first electrode structure ST1. The first electrode structure ST1 may include first electrodes EL1 and first insulating layers ILD1, which are alternately stacked on the semiconductor layer 100 in the third direction D3. The second electrode structure ST2 may include second electrodes EL2 and second insulating layers ILD2, which are alternately stacked on the first electrode structure ST1 in the third direction D3. The lowermost one of the second insulating layers ILD2 may be disposed on the uppermost one of the first insulating layers ILD1.

Even-numbered ones of the electrodes GE1 and GE2 of the electrode structure ST may include pad portions PAD, which are disposed in the first direction D1, and the cell contact plugs CPLG may be coupled to the pad portions PAD of the even-numbered ones of the electrodes GE1 and GE2, respectively. In an embodiment, the pad portions PAD of 4n-th ones of the electrodes GE1 and GE2 of the electrode structure ST may be disposed in the first direction D1. The side surfaces of the (4n-1), (4n-2), (4n-3)-th ones of the electrodes GE1 and GE2 may be aligned to side surfaces of the 4n-th ones of the electrodes GE1 and GE2. The cell contact plugs CPLG may be coupled to the pad portions PAD of the 4n-th ones of the electrodes GE1 and GE2. In an embodiment, the pad portions PAD of the electrodes GE1 and GE2 may be located at positions that are different from each other in horizontal and vertical directions.

Each of the electrodes GE1 and GE2 may include an electrode portion (not shown) on the cell array region CAR and a pad portion PAD on the connection region CNR. The electrode portion may have a first thickness, and the pad portion PAD may have a second thickness larger than the first thickness. A bottom surface of the electrode portion and a bottom surface of the pad portion PAD may be substantially coplanar with each other and may be in contact with an interlayer insulating layer ILD. A top surface of the pad portion PAD may be located at a level higher than a top surface of the electrode portion. The top surface of the pad portion PAD may be in contact with the cell contact plug CPLG penetrating a planarization insulating layer 120.

The electrode structure ST may include mold patterns MP, which are located at the same levels as the electrodes GE1 and GE2 in the connection region CNR, and each of which is interposed between the insulating layers ILD. The mold patterns MP may be formed of or include an insulating material different from the insulating layers ILD. The mold patterns MP may be formed of or include at least one of silicon nitride, silicon oxynitride, or silicon germanium. Furthermore, the mold patterns MP may be overlapped with the penetration insulating pattern 111, when viewed in a plan view.

The planarization insulating layer 120 may be provided to cover the pad portions PAD of the electrode structure ST having the stepwise structure. The planarization insulating layer 120 may have a substantially flat top surface. The planarization insulating layer 120 may include a single insulating layer or a plurality of stacked insulating layers. First to fourth interlayer insulating layers 130, 140, 150, and 160 may be sequentially stacked on the planarization insulating layer 120.

First, second, and third separation structures SS1, SS2, and SS3 and middle separation structures MSS may be provided on the semiconductor layer 100 to penetrate the electrode structure ST. Each of the first, second, and third separation structures SS1, SS2, and SS3 and the middle separation structures MSS may include an insulating layer covering a side surface of the electrode structure ST. Each of the first, second, and third separation structures SS1, SS2, and SS3 and the middle separation structures MSS may have a single-or multi-layered structure. The first, second, and third separation structures SS1, SS2, and SS3 may have top surfaces that are located at substantially the same level.

In the cell array region CAR, the first separation structures SS1 may be extended from a first connection region CNR1 in the first direction D1 and may be spaced apart from each other in the second direction D2 crossing the first direction D1. The first separation structure SS1 may be provided in a first trench TR1, which is recessed from a top surface of the third interlayer insulating layer 150 toward a top surface of the semiconductor substrate 10. The first separation structures SS1 may be in contact with the source structure CST, in the cell array region CAR. The first separation structures SS1 may include a lower portion penetrating the support conductive pattern SP and an upper portion penetrating the electrode structure ST, and here, a width of the lower portion may be smaller than a width of the upper portion.

The second separation structure SS2 may penetrate the electrode structure ST in the cell array region CAR. The second separation structure SS2 may be disposed between the first separation structures SS1. When measured in the first direction D1, a length of the second separation structure SS2 may be smaller than a length of the first separation structure SS1. The second separation structure SS2 may be provided in a second trench TR2, which is recessed from the top surface of the third interlayer insulating layer 150 toward the top surface of the semiconductor substrate 10.

The middle separation structures MSS may be provided in the cell array region CAR and may be extended in the first direction D1 to penetrate a portion of the electrode structure ST. The middle separation structures MSS may be disposed between the first and second separation structures SS1 and SS2, which are adjacent to each other in the second direction D2, and in an embodiment, two or more middle separation structures MSS may be provided between the first and second separation structures SS1 and SS2.

The middle separation structures MSS may be provided to penetrate upper electrodes GE2, which are upper ones of the electrodes GE1 and GE2 of the electrode structure ST, and the upper electrodes GE2 may be spaced apart from each other by the middle separation structures MSS in a horizontal direction (e.g., in the second direction D2). The upper electrodes GE2 may be the gate upper lines UL1 and UL2 described with reference to FIG. 1. In other words, the upper electrodes GE2 may be used as the gate electrodes of the string selection transistors UT1 and UT2 described with reference to FIG. 1.

Referring to FIG. 6B, the middle separation structures MSS may be provided to penetrate vertically adjacent two ones of the upper electrodes GE2, but the inventive concept is not limited to this example or a specific embodiment. Each of the middle separation structures MSS may penetrate vertically adjacent three ones of the upper electrodes GE2.

The middle separation structure MSS may be provided in a third trench TR3, which is recessed from a top surface of the first interlayer insulating layer 130 toward the top surface of the semiconductor substrate 10. In an embodiment, a top surface of the middle separation structure MSS may be located at a level that is higher than top surfaces of the vertical structures VS. In an embodiment, the top surface of the middle separation structure MSS may be located at the same level as the top surface of the first interlayer insulating layer 130. A level of a bottom surface of the middle separation structure MSS may vary, by region, depending on whether the middle separation structure MSS is overlapped with dummy vertical structures DVS.

In the connection region CNR, the third separation structures SS3 may be spaced apart from the first and second separation structures SS1 and SS2 and may be provided to penetrate the planarization insulating layer 120 and the electrode structure ST. The third separation structures SS3 may be extended in the first direction D1. The third separation structures SS3 may be spaced apart from each other in the first and second directions D1 and D2.

The vertical structures VS and the dummy vertical structures DVS may penetrate the electrode structure ST and a source structure SCT in the cell array region CAR. When viewed in a plan view, the vertical structures VS may be arranged in a linear or zigzag shape. The dummy vertical structures DVS may be arranged in a direction (e.g., the first direction D1) and may be overlapped with the middle separation structures MSS vertically (e.g., in the third direction D3).

Each of the vertical structures VS may include a first vertical extended portion penetrating the first electrode structure ST1, a second vertical extended portion penetrating the second electrode structure ST2, and an extension portion between the first and second vertical extended portions. The extension portion may be provided in the uppermost one of the first insulating layers ILD1. A diameter of the vertical structure VS may be rapidly increased at the expanded portion.

The first interlayer insulating layer 130 may be disposed on the planarization insulating layer 120 to cover the top surfaces of the vertical structures VS.

Referring to FIG. 7, each of the vertical structures VS may include a gapfill insulating pattern VI, a vertical semiconductor pattern VP enclosing a side surface of the gapfill insulating pattern VI, and a data storage pattern DSP enclosing a side surface of the vertical semiconductor pattern VP.

In detail, the vertical semiconductor pattern VP may have a tube shape, pipe shape or macaroni shape with a closed bottom. The vertical semiconductor pattern VP may be a U-shaped structure whose internal space is filled with the gapfill insulating pattern VI. The vertical semiconductor pattern VP may be formed of or include at least one of semiconductor materials (e.g., silicon (Si) or germanium (Ge)). The vertical semiconductor pattern VP, which is formed of or includes a semiconductor material, may be used as channel regions of the upper transistors UT1 and UT2, the memory cell transistors MCT, and the lower transistors LT1 and LT2 described with reference to FIG. 1. A bottom surface of the vertical semiconductor pattern VP may be located at a level lower than a bottom surface of the source conductive pattern SC.

A portion of the side surface of the vertical semiconductor pattern VP may be in contact with the source conductive pattern SC. In more detail, the source conductive pattern SC may include a horizontal portion SC1, which is provided between the support conductive pattern SP and the semiconductor layer 100 and is parallel to the electrode structure ST, and a sidewall portion SC2, which is in contact with or encloses a portion of the side surface of the vertical semiconductor pattern VP. In the source conductive pattern SC, a top surface of the horizontal portion SC1 may be in contact with a bottom surface of the support conductive pattern SP, and a bottom surface of the horizontal portion SC1 may be in contact with the top surface of the semiconductor layer 100. The sidewall portion SC2 of the source conductive pattern SC may be extended from the horizontal portion SC1 to have a vertically protruding shape and to be in contact with a portion of a side surface of the conductive support pattern SP.

The data storage pattern DSP may be extended in the third direction D3 to enclose the side surface of each of the vertical semiconductor patterns VP. The data storage pattern DSP may have a tube shape, a pipe shape or macaroni-shape with an open top and an open bottom. A bottom surface of the data storage pattern DSP may be located at a level between the top and bottom surfaces of the support conductive pattern SP. The data storage pattern DSP may be composed of one or more layers. In an embodiment, the data storage pattern DSP may be a data storing layer of a NAND FLASH memory device and may include a tunnel insulating layer TIL, a charge storing layer CIL, and a blocking insulating layer BLK, which are sequentially stacked on the side surface of the vertical semiconductor pattern VP. For example, the charge storing layer CIL may be a trap insulating layer, a floating gate electrode, or an insulating layer with conductive nanodots.

Furthermore, a lower dummy data storage pattern RDSP may be disposed in the semiconductor layer 100 to be vertically spaced apart from the data storage pattern DSP. The dummy data storage pattern RDSP may have the same layer structure as the data storage pattern DSP.

Referring back to FIGS. 5, 6A, and 6B, the penetration insulating pattern TIP may penetrate a portion of the electrode structure ST in the connection region CNR. The penetration insulating pattern TIP may be provided between the electrodes GE1 and GE2 and the mold patterns MP. The penetration insulating pattern TIP may enclose the mold patterns MP, when viewed in a plan view. The penetration insulating pattern TIP may include an insulating layer covering the side surface of the electrode structure ST and the side surfaces of the mold patterns MP. The penetration insulating pattern TIP may be in contact with the top surface of the support conductive pattern SP and/or the top surface of the penetration insulating pattern 111. The top surface of the penetration insulating pattern TIP may be located at a level different from the top surfaces of the first, second, and third separation structures SS1, SS2, and SS3.

The second interlayer insulating layer 140 may be disposed on the first interlayer insulating layer 130 to cover the top surface of the penetration insulating pattern TIP.

The penetration contact plugs TPLG may be provided in the connection region CNR to vertically penetrate the mold patterns MP of the electrode structure ST and the penetration insulating pattern 111 and may be connected to the peripheral circuit lines PLP. The penetration contact plugs TPLG may be electrically connected to the cell contact plugs CPLG through the conductive lines CL. A first spacer SP1, which is formed of an insulating material, may be provided to enclose a side surface of each penetration contact plug TPLG.

First sidewall insulating patterns CS1 may be disposed between the mold patterns MP and the first spacer SP1 to enclose a side surface of each penetration contact plug TPLG. The first sidewall insulating patterns CS1 may include an insulating material (e.g., silicon oxide) different from the mold patterns MP.

In the connection region CNR, peripheral contact plugs PPLG may be provided to penetrate the planarization insulating layer 120 and may be coupled to the semiconductor layer 100. The peripheral contact plugs PPLG may be horizontally spaced apart from the electrode structure ST. Top surfaces of the peripheral contact plugs PPLG may be located at substantially the same level as top surfaces of the penetration contact plugs TPLG. In other words, the top surfaces of the peripheral contact plugs PPLG may be coplanar with the top surfaces of the penetration contact plugs TPLG. A second spacer SP2, which is formed of an insulating material, may be provided to enclose a side surface of each peripheral contact plug PPLG.

The third interlayer insulating layer 150 may be disposed on the second interlayer insulating layer 140 to cover the top surfaces of the penetration contact plugs TPLG and the top surfaces of the peripheral contact plugs PPLG.

The dummy structures DS may penetrate the planarization insulating layer 120, the electrode structure ST, the support conductive pattern SP, and the dummy insulating patterns 101p, 103p, and 105p in the connection region CNR. The dummy structures DS may penetrate the pad portion PAD of each of the electrodes GE1 and GE2. Top surfaces of the dummy structures DS may be substantially coplanar with the top surfaces of the penetration contact plugs TPLG and the top surfaces of the peripheral contact plugs PPLG.

The dummy structures DS may be disposed to enclose each of the cell contact plugs CPLG. The top surfaces of the dummy structures DS may have various shapes (e.g., circular, elliptical, and bar shapes). In the case where the top surfaces of the dummy structures DS have an elliptical shape, the dummy structures DS may have longitudinal axes that are oriented in different directions, in each pad portion PAD. The dummy structures DS may be provided between adjacent ones of the cell contact plugs CPLG.

Although the bit lines are not illustrated in the plan views, but as shown in FIGS. 6A and 6B, the bit lines BL may be disposed on the fourth interlayer insulating layer 160 in the cell array region CAR to cross the electrode structure ST and extend in the second direction D2. The bit lines BL may be electrically connected to the vertical structures VS through lower and upper bit line contact plugs BCTa and BCTb.

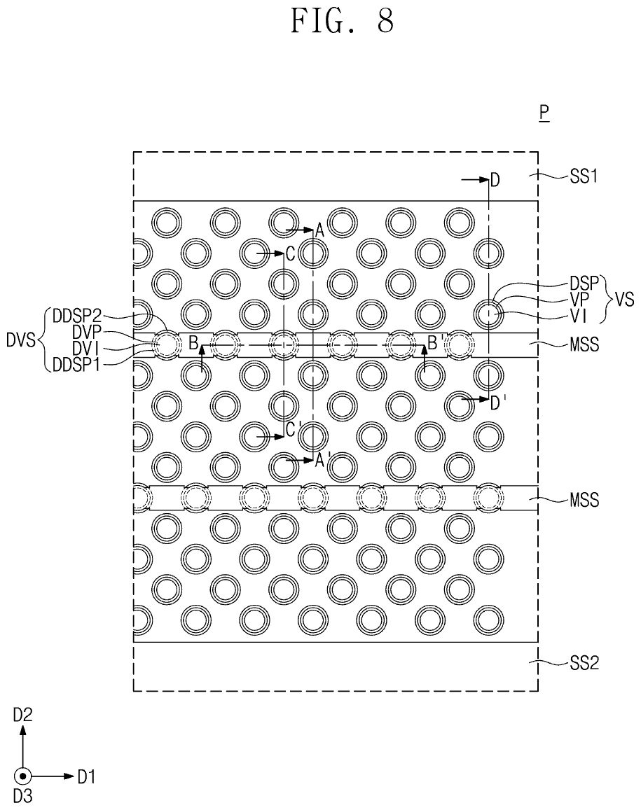

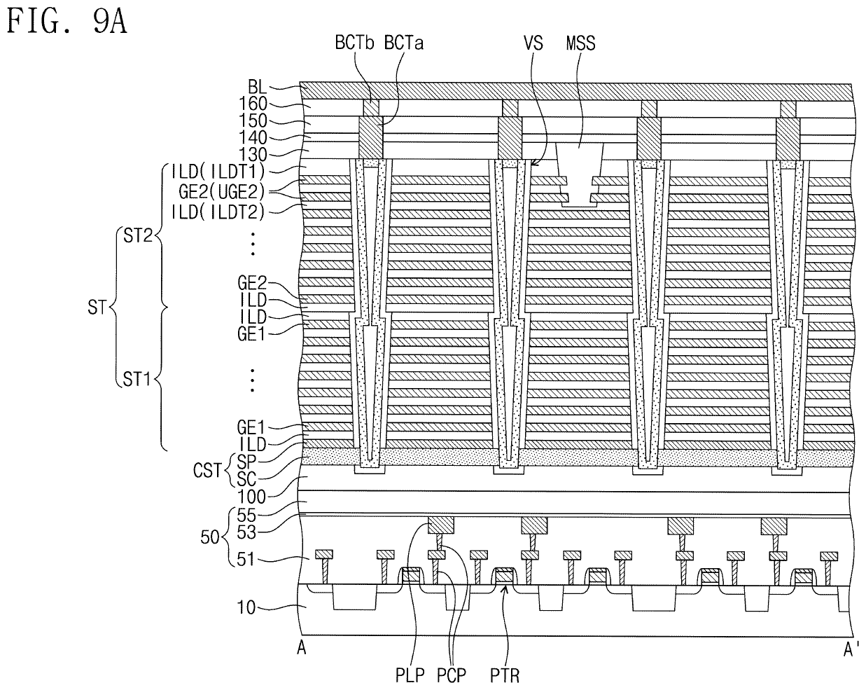

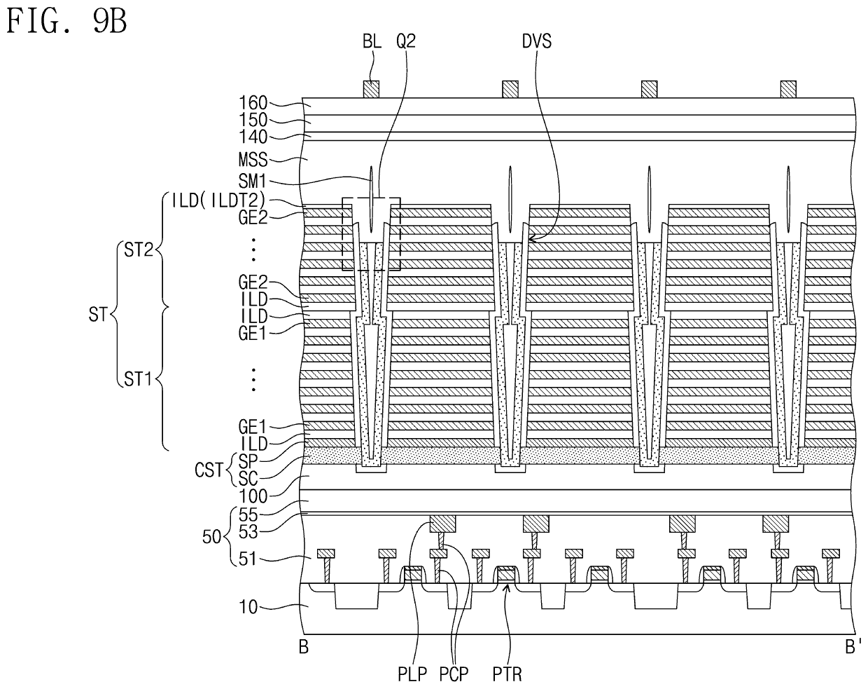

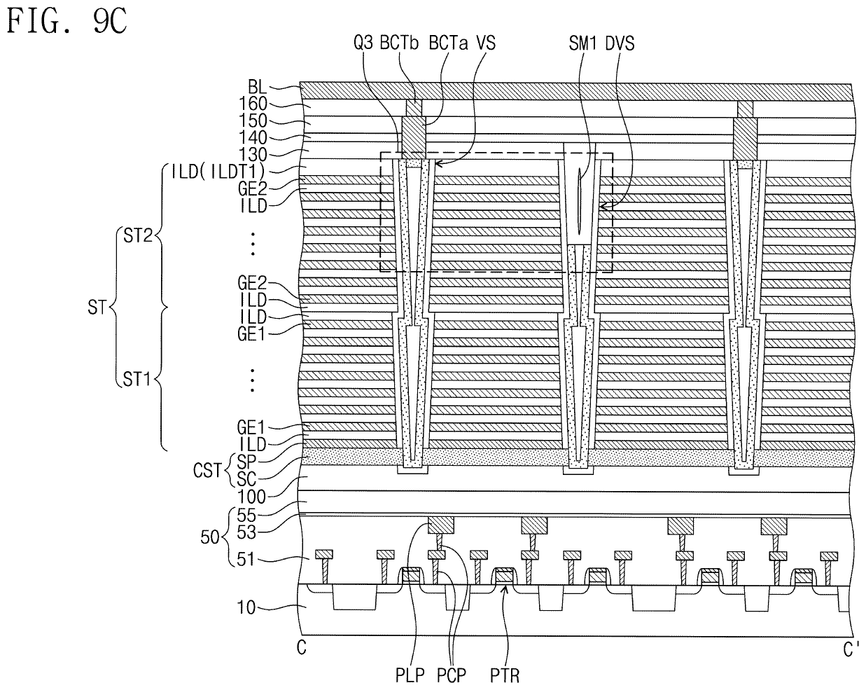

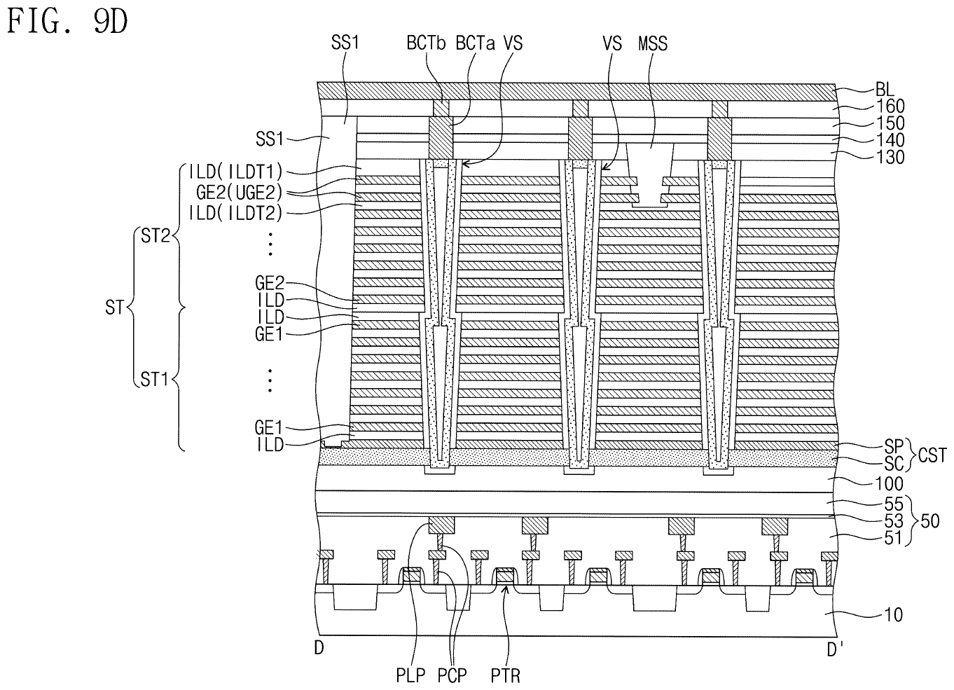

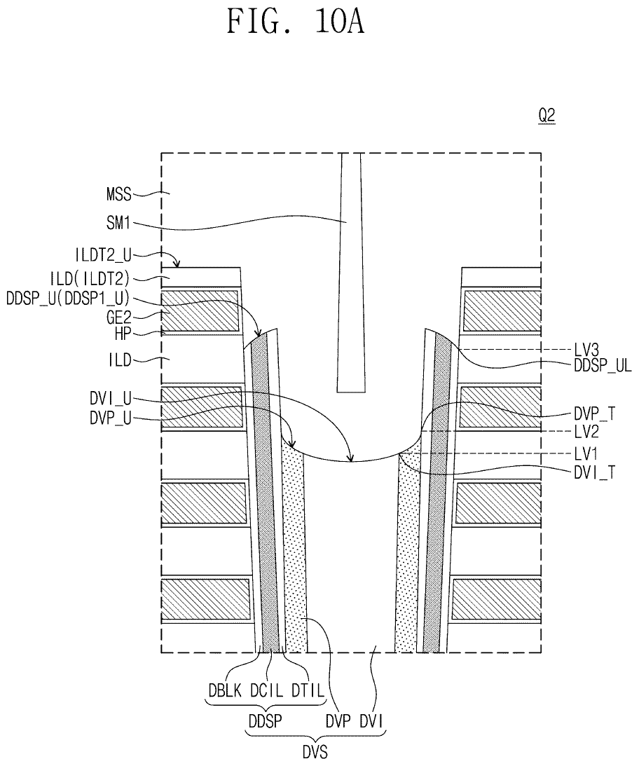

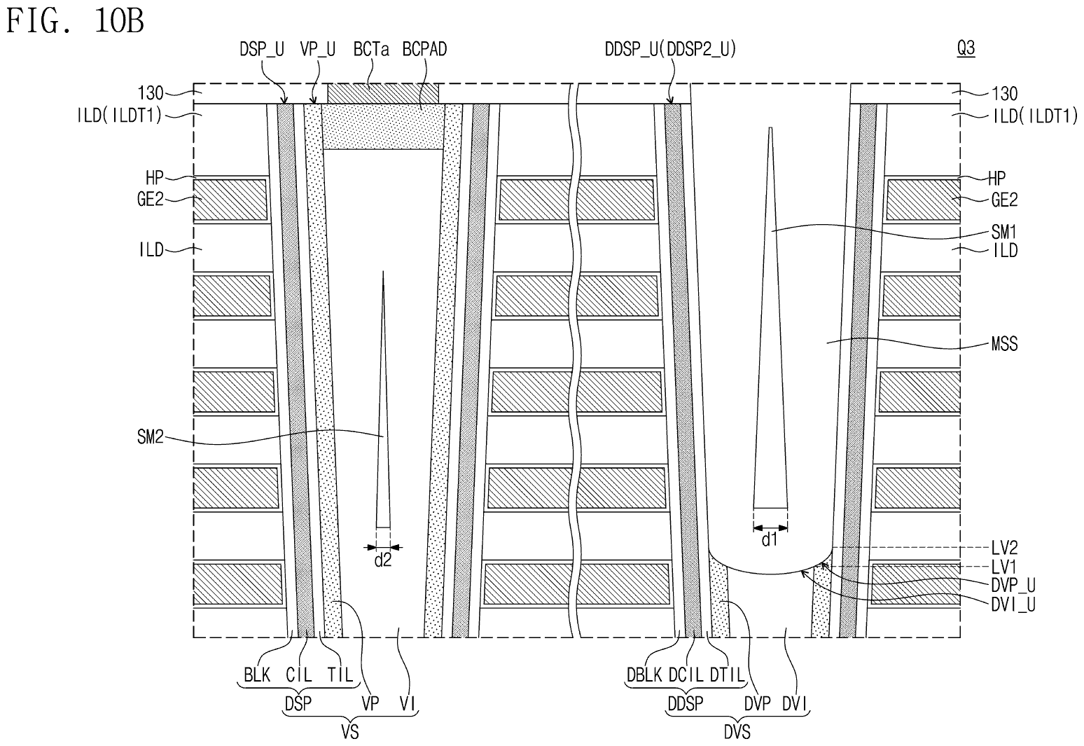

FIG. 8 is an enlarged plan view illustrating a portion ‘P’ of FIG. 5. FIGS. 9A, 9B, 9C, and 9D are sectional views, which are respectively taken along lines A-A′, B-B′, C-C′, and D-D′ of FIG. 8 to illustrate a semiconductor device according to an embodiment of the inventive concept. FIG. 10A is an enlarged sectional view illustrating a portion ‘Q2’ of FIG. 9B. FIG. 10B is an enlarged sectional view illustrating a portion ‘Q3’ of FIG. 9C. The middle separation structure MSS and the dummy vertical structure DVS in the cell array region CAR will be described in more detail in the following description, for convenience in description, and the previously-described technical features will be omitted.

Referring to FIGS. 5 and 8, as described above, the middle separation structure MSS may be extended in the first direction D1 and may be spaced apart from each other in the second direction D2. The middle separation structure MSS, which is extended in the first direction D1, may be overlapped with the dummy vertical structure DVS vertically (e.g., in the third direction D3). In more detail, the middle separation structure MSS may cover at least a portion of a top surface of the dummy vertical structure DVS (e.g., a top surface of a dummy gapfill insulating pattern DVI, a top surface of a dummy vertical semiconductor pattern DVP, a top surface of a portion DDSP1 of a dummy data storage pattern DDSP1, DDSP2).

Referring to FIGS. 5, 8, 9A, and 9D, the middle separation structure MSS may be extended in the first direction D1 and may penetrate upper electrodes UGE2, which are included in the electrodes GE1 and GE2, and upper insulating layers ILDT1 and ILDT2, which are included in the interlayer insulating layer ILD. Thus, portions of the upper electrodes UGE2 may be separated from each other horizontally (e.g., in the second direction D2) by the middle separation structure MSS. The upper insulating layers ILDT1 and ILDT2 between the upper electrodes UGE2 may have side surfaces, which are recessed from the upper electrodes UGE2 in the second direction D2 that is perpendicular to an extension direction of the middle separation structure MSS or to the first direction D1. The middle separation structure MSS may be provided to partially fill spaces between the upper electrodes UGE2 and may be in contact with top, side, and bottom surfaces of the upper electrodes UGE2. The top surface of the middle separation structure MSS may be located at a level lower than the top surface of the first separation structure SS1, and the bottom surface of the middle separation structure MSS may be located at a level higher than the bottom surface of the first separation structure SS1.

Next, referring to FIGS. 5, 8, 9B, and 10A, the dummy vertical structures DVS may be vertically overlapped with the middle separation structure MSS. The dummy vertical structure DVS may include the dummy gapfill insulating pattern DVI, the dummy vertical semiconductor pattern DVP enclosing a side surface of the dummy gapfill insulating pattern DVI, and the dummy data storage pattern DDSP enclosing a side surface of the dummy vertical semiconductor pattern DVP. The dummy gapfill insulating pattern DVI, the dummy vertical semiconductor pattern DVP, and the dummy data storage pattern DDSP may include the same or similar materials as the gapfill insulating pattern VI, the vertical semiconductor pattern VP, and the data storage pattern DSP of the vertical structures VS described above.

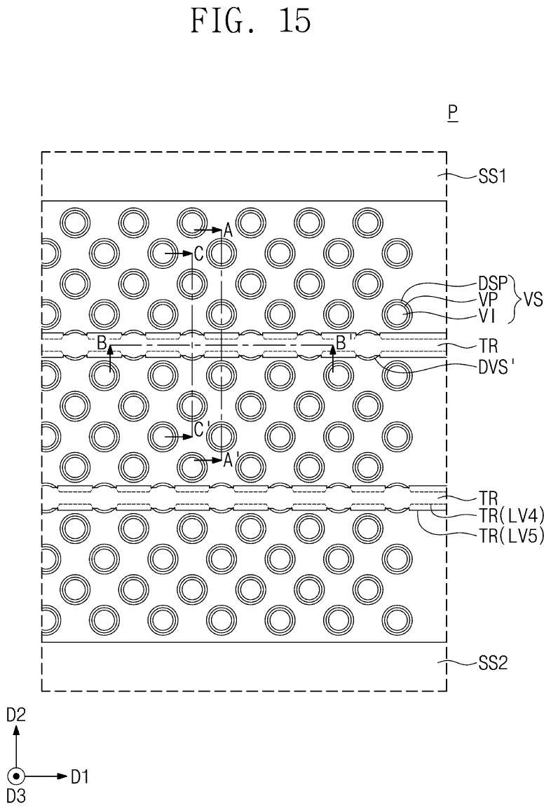

In the dummy vertical structure DVS, a top surface DVI_U of the dummy gapfill insulating pattern DVI and a top surface DVP_U of the dummy vertical semiconductor pattern DVP may be recessed, and a top surface DDSP1_U of the dummy data storage pattern DDSP may be convex in an upward direction. Here, the recessed top surface DVI_U of the dummy gapfill insulating pattern DVI and the recessed top surface DVP_U of the dummy vertical semiconductor pattern DVP may be located at a level lower than a top surface DDSP_U of the dummy data storage pattern DDSP. In other words, the uppermost portion DVP_T of the dummy vertical semiconductor pattern DVP and the uppermost portion DVI_U of the dummy gapfill insulating pattern DVI may be located at a level lower than the top surface DDSP_U of the dummy data storage pattern DDSP. For example, the uppermost portion DVI_U of the dummy gapfill insulating pattern DVI may be located at a first level LV1, the uppermost portion DVP_T of the dummy vertical semiconductor pattern DVP may be located at a second level LV2 higher than the first level LV1, and the lowermost portion DDSP_UL of the top surface of the dummy data storage pattern DDSP may be located at a third level LV3 higher than the second level LV2. The uppermost portion DVP_T of the dummy vertical semiconductor pattern DVP may be in contact with a side surface of the dummy data storage pattern DDSP. The middle separation structure MSS may cover a top surface ILDT2_U of the upper insulating layer ILDT2, the top surface DDSP_U and the side surface of the dummy data storage pattern DDSP, the top surface DVP_U of the dummy vertical semiconductor pattern DVP, and the recessed top surface DVI_U of the dummy gapfill insulating pattern DVI. The middle separation structure MSS may cover the side surface of the electrode structure ST, in the second direction D2 perpendicular to the first direction D1, and may cover the side surface of the dummy data storage pattern DDSP in the dummy vertical structure DVS. The afore-described profiles of the top surfaces DVI_U and DVP_U may be a result of a subsequent etching process of forming the trench TR, which will be described with reference to FIGS. 15 to 17.

The middle separation structure MSS may cover the top surface DDSP1_U and the side surface of the dummy data storage pattern DDSP and may also cover the top surface DVI_U of the dummy gapfill insulating pattern DVI and the top surface DVP_U of the dummy vertical semiconductor pattern DVP. In an embodiment, the middle separation structure MSS may include a first seam SM1, which is vertically overlapped with the dummy gapfill insulating pattern DVI.

Referring to FIGS. 5, 8, 9C, and 10B, the vertical structure VS may include the gapfill insulating pattern VI, the vertical semiconductor pattern VP enclosing the side surface of the gapfill insulating pattern VI, the data storage pattern DSP enclosing the side surface of the vertical semiconductor pattern VP, and a bit line conductive pad BCPAD on the gapfill insulating pattern VI, as described with reference to FIG. 7. A top surface VP_U of the vertical semiconductor pattern VP and a top surface DSP_U of the data storage pattern DSP may be coplanar with each other and may also be coplanar with a top surface of the bit line conductive pad BCPAD. The bit line conductive pad BCPAD may be in contact with a top surface of the gapfill insulating pattern VI and may be connected to the lower bit line contact plug BCTa. The bit line conductive pad BCPAD may be an impurity region or may be formed of or include a conductive material. The top surface DVI_U of the dummy gapfill insulating pattern DVI and the top surface DVP_U of the dummy vertical semiconductor pattern DVP may be located at a level lower than a bottom surface of the bit line conductive pad BCPAD. In other words, the uppermost portion DVP_T of the dummy vertical semiconductor pattern DVP and the uppermost portion DVI_U of the dummy gapfill insulating pattern DVI described with reference to FIG. 10A may be located a level lower than the bottom surface of the bit line conductive pad BCPAD.

The first seam SM1 may be formed in the middle separation structure MSS and on the dummy gapfill insulating pattern DVI, and a second seam SM2 may be formed in the gapfill insulating patterns VI of the vertical structures VS. The first seam SM1 in the middle separation structure MSS may be formed to be larger than the second seam SM2 in the gapfill insulating pattern VI. In other words, a width d1 of the first seam SM1 may be larger than a width d2 of the second seam SM2, and a height of the first seam SM1 may be larger than a height of the second seam SM2. Here, the width dl of the first seam SM1 may be the largest width of the first seam SM1 in the second direction D2, and the width d2 of the second seam SM2 may be the largest width of the second seam SM2 in the second direction D2. For example, in the case where the first and second seams SM1 and SM2 are formed in a cone shape, the widths d1 and d2 of the first and second seams SM1 and SM2 may correspond to the diameters of the bases of their respective cones.

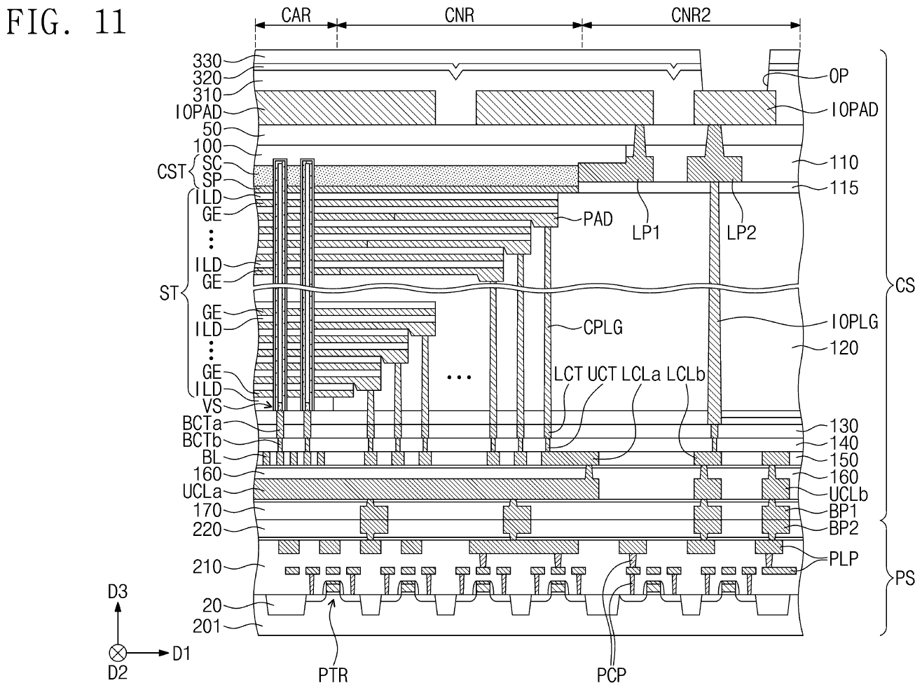

FIG. 11 is a sectional view illustrating a semiconductor device according to an embodiment of the inventive concept. In the following description, an element previously described with reference to FIGS. 5, 6B, and 6B may be identified by the same reference number without repeating an overlapping description thereof, for the sake of brevity.

Referring to FIG. 11, the semiconductor device according to an embodiment of the inventive concept may have a chip-to-chip (C2C) structure. For the C2C structure, an upper chip including the cell array structure CS may be fabricated on a first wafer, a lower chip including the peripheral circuit structure PS may be fabricated on a second wafer different from the first wafer, and the upper chip and the lower chip may be connected to each other through a bonding method. The bonding method may mean a way of electrically connecting a bonding metal, which is formed in the uppermost metal layer of the upper chip, to a bonding metal, which is formed in the uppermost metal layer of the lower chip. For example, in the case where the bonding metal is formed of copper (Cu), the bonding method may be a Cu-to-Cu bonding method, but in an embodiment, aluminum (Al) or tungsten (W) may be used as the bonding metal.

The cell array structure CS may include a memory cell array, which includes memory cells that are three-dimensionally arranged on the semiconductor layer 100. The memory cell array may be electrically connected to first bonding pads BP1.

In more detail, the cell array structure CS may include the semiconductor layer 100, the source structure CST, the electrode structure ST, the vertical structures VS, the bit lines BL, the cell contact plugs CPLG, and an input/output contact plug IOPLG.

The cell array structure CS may include the cell array region CAR and first and second connection regions CNR and CNR2, and the first connection region CNR may be placed between the cell array region CAR and the second connection region CNR2 in the first direction D1.

In the cell array region CAR and the first connection region CNR, the semiconductor layer 100 of the cell array structure CS may be disposed on the top surface of the lower insulating layer 50. The semiconductor layer 100 may be formed of or include at least one of semiconductor, insulating, or conductive materials.

The source structure CST may be disposed on the semiconductor layer 100. The source structure CST may include the source conductive pattern SC and the support conductive pattern SP on the source conductive pattern SC. The source structure CST may be parallel to the top surface of the semiconductor layer 100 and may be extended in the first direction D1 to be parallel to the electrode structure ST, in the cell array region CAR and the first connection region CNR.

An insulating gapfill layer 110 may be disposed in the second connection region CNR2 to cover a side surface of the semiconductor layer 100 and a side surface of the source structure CST. The insulating gapfill layer 110 may have a top surface, which is substantially coplanar with the top surface of the source structure CST. A top surface of the insulating gapfill layer 110 may be located at substantially the same level as the top surface of the source conductive pattern SC or the top surface of the support conductive pattern SP. The insulating gapfill layer 110 may be formed of or include an insulating material (e.g., silicon oxide and silicon nitride).

A first pad conductive pattern LP1 and a second pad conductive pattern LP2 may be provided in the insulating gapfill layer 110.

The first pad conductive pattern LP1 may be provided between the semiconductor layer 100 and the source structure CST and may be in contact with a portion of the semiconductor layer 100. The first pad conductive pattern LP1 may include a via portion, which is provided below a bottom surface of the lower insulating layer 50 and is in contact with an input/output pad IOPAD, and a pad portion, which is connected to the via portion and is placed in the insulating gapfill layer 110 to be in contact with the semiconductor layer 100. The first pad conductive pattern LP1 may have a substantially flat top surface. In an embodiment, a top surface of the first pad conductive pattern LP1 may be located at substantially the same level as the top surface of the source conductive pattern SC or the top surface of the support conductive pattern SP. The top surface of the first pad conductive pattern LP1 may be substantially coplanar with a top surface of the second pad conductive pattern LP2. A side surface of the first pad conductive pattern LP1 may be in contact with at least a portion of the source structure CST (e.g., a side surface of the source conductive pattern SC). Portions of the first pad conductive pattern LP1 may be in direct contact with the insulating gapfill layer 110 and a first insulating pattern 115. The first pad conductive pattern LP1 may have a first thickness on the semiconductor layer 100 and a second thickness, which is larger than the first thickness, in the insulating gapfill layer 110.

A metal silicide layer may be interposed between the semiconductor layer 100 and a portion of the first pad conductive pattern LP1 and between the source structure CST and the first pad conductive pattern LP1.

The second pad conductive pattern LP2 may be disposed in a portion of the insulating gapfill layer 110, which is spaced apart from the side surface of the semiconductor layer 100. The second pad conductive pattern LP2 may be coupled to the input/output pad IOPAD, which is provided on the lower insulating layer 50. The second pad conductive pattern LP2 may include a via portion, which is provided below the bottom surface of the lower insulating layer 50 and is in contact with the input/output pad IOPAD, and a pad portion, which is connected to the via portion and is placed in the insulating gapfill layer 110.

Next, the electrode structure ST may be disposed on the source structure CST. The electrode structure ST may include electrodes GE and insulating layers ILD, which are alternately stacked in a third direction D3 (i.e., a vertical direction), and here, the third direction D3 may be perpendicular to first and second directions D1 and D2 crossing each other.

Each of the electrodes GE may include the electrode portion on the cell array region CAR and the pad portion PAD on the first connection region CNR. The pad portion PAD may be thicker than the electrode portion. The electrodes GE may be stacked on the source structure CST to have a staircase structure in the first connection region CNR. The pad portions PAD of the electrodes GE may be located at positions that are different from each other in horizontal and vertical directions. The cell contact plugs CPLG may be coupled to the pad portions PAD of the electrodes GE, respectively.

The vertical structures VS may penetrate the electrode structure ST in the cell array region CAR. Each of the vertical structures VS may include the vertical semiconductor pattern VP and the data storage pattern DSP enclosing the side surface of the vertical semiconductor pattern VP, as described with reference to FIG. 7.

In addition, as described above, dummy vertical structures (not shown) may be provided in the first connection region CNR to penetrate the pad portions PAD of the electrodes GE. The planarization insulating layer 120 may cover the staircase structure of the electrode structure ST. The planarization insulating layer 120 may have a substantially flat top surface.

The cell contact plugs CPLG may be provided to penetrate the first and second interlayer insulating layers 130 and 140 and the planarization insulating layer 120 and may be couped to the pad portions PAD of the electrodes GE, respectively. The smaller the distance to the cell array region CAR, the smaller the vertical lengths of the cell contact plugs CPLG. The cell contact plugs CPLG may have top surfaces that are substantially coplanar with each other.

The input/output contact plug IOPLG may be provided to penetrate the first and second interlayer insulating layers 130 and 140 and the planarization insulating layer 120 and may be coupled to the second pad conductive pattern LP2. The input/output contact plug IOPLG may be electrically connected to the input/output pad IOPAD through the second pad conductive pattern LP2.

The bit lines BL may be disposed on the fourth interlayer insulating layer 160 and in the cell array region CAR and may be extended in the second direction D2 to cross the electrode structure ST. The bit lines BL may be electrically connected to the vertical structures VS through lower and upper bit line contact plugs BCTa and BCTb.

First lower conductive lines LCLa may be disposed on the fourth interlayer insulating layer 160 in the first connection region CNR and may be coupled to the cell contact plugs CPLG through lower and upper contact plugs LCT and UCT.

Second lower conductive lines LCLb may be disposed on the fourth interlayer insulating layer 160 in the second connection region CNR2 and may be coupled to the input/output contact plugs IOPLG through the lower and upper contact plugs LCT and UCT.

The first and second upper conductive lines UCLa and UCLb may be disposed in the fourth interlayer insulating layer 160. The first upper conductive lines UCLa may be electrically connected to the first lower conductive lines LCLa, in the cell array region CAR and the first connection region CNR. The second upper conductive lines UCLb may be electrically connected to the second lower conductive lines LCLb, in the second connection region CNR2.

The first and second lower conductive lines LCLa and LCLb and the first and second upper conductive lines UCLa and UCLb may be formed of or include at least one of, for example, metallic materials (e.g., tungsten, copper, and aluminum), conductive metal nitride materials (e.g., titanium nitride and tantalum nitride), or transition metals (e.g., titanium and tantalum). For example, the first and second lower conductive lines LCLa and LCLb may be formed of or include a material (e.g., tungsten) having relatively high electric resistivity, and the first and second upper conductive lines UCLa and UCLb may be formed of or include a material (e.g., copper) having relatively low electric resistivity.

The first bonding pads BP1 may be provided in an uppermost interlayer insulating layer 170. The first bonding pads BP1 may be electrically connected to the first and second upper conductive lines UCLa and UCLb. The first bonding pads BP1 may be formed of or include at least one of aluminum, copper, or tungsten.

The peripheral circuit structure PS may include the peripheral circuits PTR, which are formed on a semiconductor substrate 201 and are used to control the memory cell array, and peripheral interlayer insulating layers 210 and 220, which are provided to cover the peripheral circuits PTR. The peripheral circuits PTR may be integrated on a top surface of the semiconductor substrate 201. A surface insulating layer may be provided on a rear surface of the semiconductor substrate 201.

The peripheral circuits PTR may include row and column decoders, a page buffer, a control circuit, and so forth. In detail, the peripheral circuits PTR may include NMOS and PMOS transistors. The peripheral circuit lines PLP may be electrically connected to the peripheral circuits PTR through the peripheral contact plugs PCP.

The peripheral interlayer insulating layers 210 and 220 may be provided on the top surface of the semiconductor substrate 201. The peripheral interlayer insulating layers 210 and 220 may be provided on the semiconductor substrate 201 to cover the peripheral circuits PTR, the peripheral contact plugs PCP, and the peripheral circuit lines PLP. The peripheral contact plugs PCP and the peripheral circuit lines PLP may be electrically connected to the peripheral circuits PTR. The peripheral interlayer insulating layers 210 and 220 may include a silicon oxide layer, a silicon nitride layer, a silicon oxynitride layer, and/or a low-k dielectric layer.

Second bonding pads BP2 may be provided in the uppermost layer (i.e., 220) of the peripheral interlayer insulating layers to correspond to the first bonding pads BP1. The second bonding pads BP2 may be electrically connected to the peripheral circuits PTR through the peripheral circuit lines PLP and the peripheral contact plugs PCP.

The second bonding pads BP2 may be electrically and physically connected to the first bonding pads BP1 by a bonding method. In other words, the second bonding pads BP2 may be in direct contact with the first bonding pads BP1.

The second bonding pads BP2 may include the same metallic material as the first bonding pads BP1. The second bonding pads BP2 may be substantially the same as the first bonding pads BP1 in terms of shape, width, or area.

The input/output pads IOPAD may be disposed below the bottom surface of the lower insulating layer 50 of the cell array structure CS. A capping insulating layer 310 may be disposed below the bottom surface of the lower insulating layer 50 to cover the input/output pads IOPAD.

A protection layer 320 and a passivation layer 330 may be sequentially formed on the capping insulating layer 310. The protection layer 320 may be, for example, a silicon nitride layer or a silicon oxynitride layer. The passivation layer 330 may be formed of or include a polyimide-based material (e.g., photo-sensitive polyimide (PSPI)).

The protection layer 320 and the passivation layer 330 may be provided to define a pad opening OP exposing a portion of the input/output pad IOPAD.

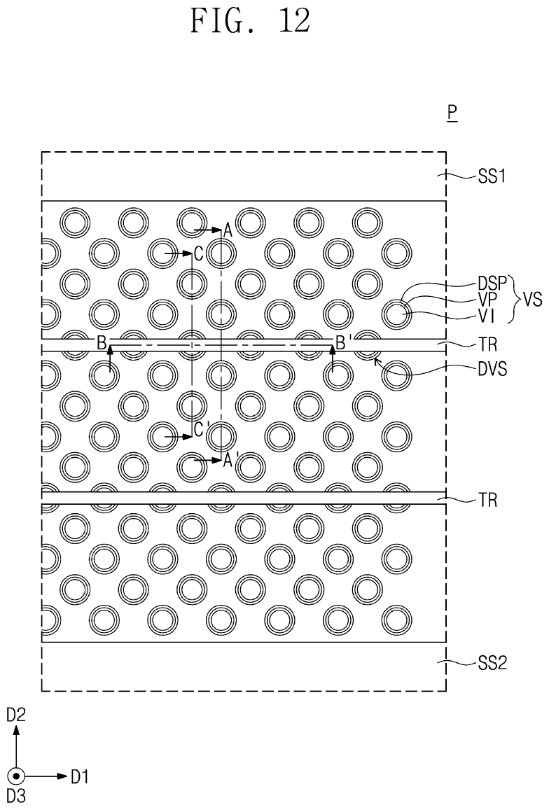

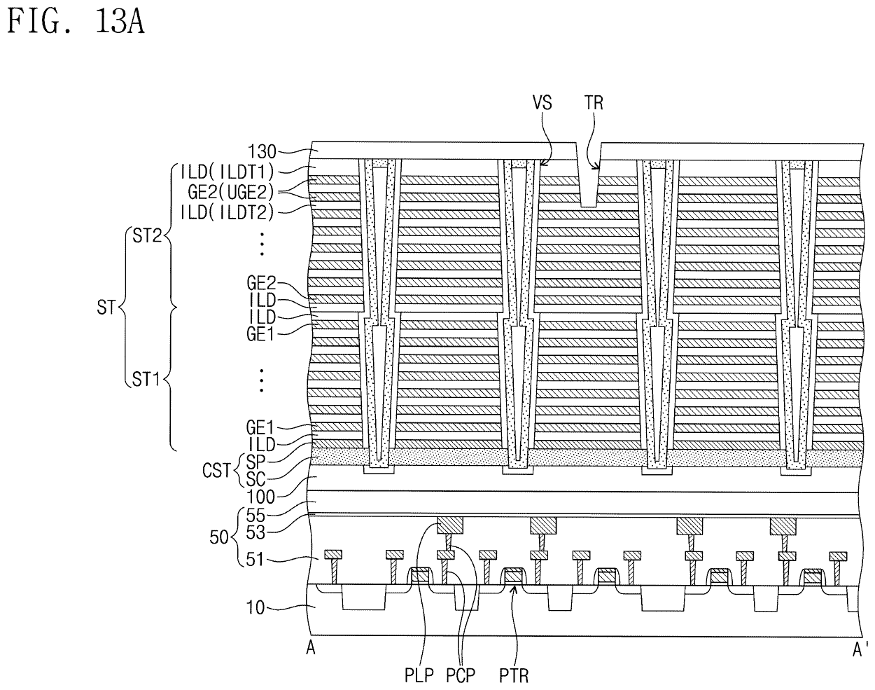

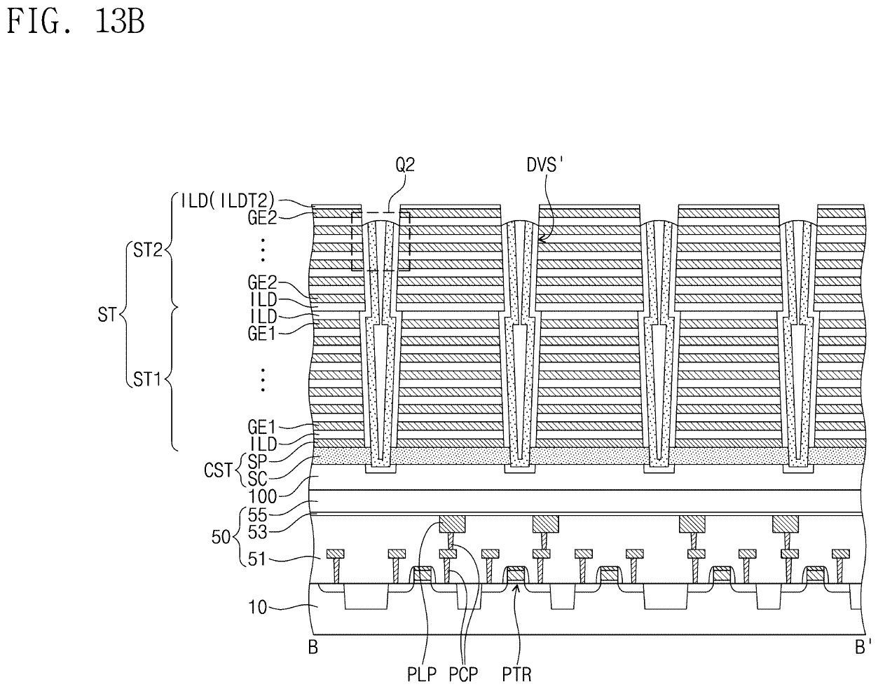

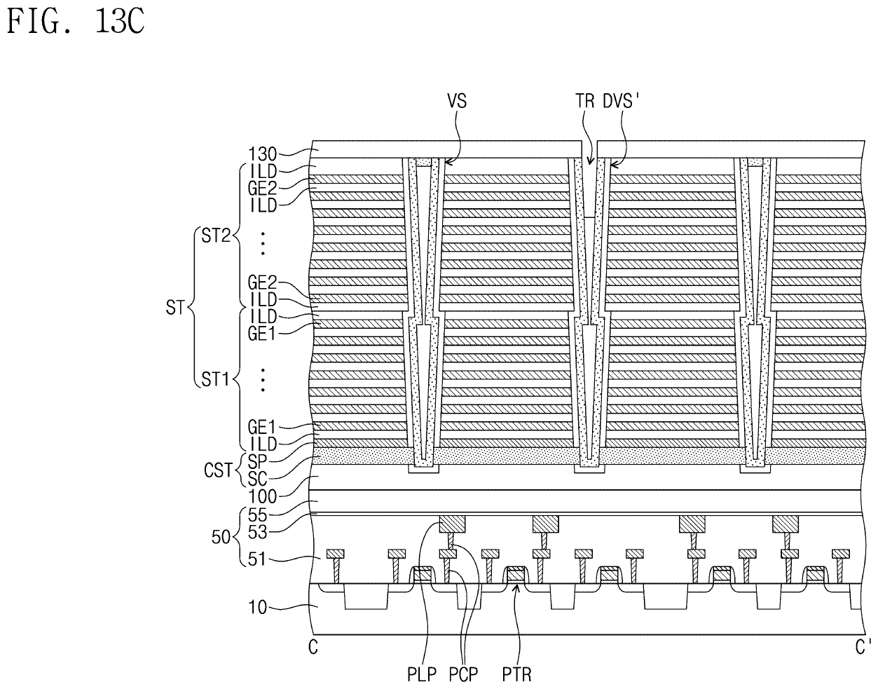

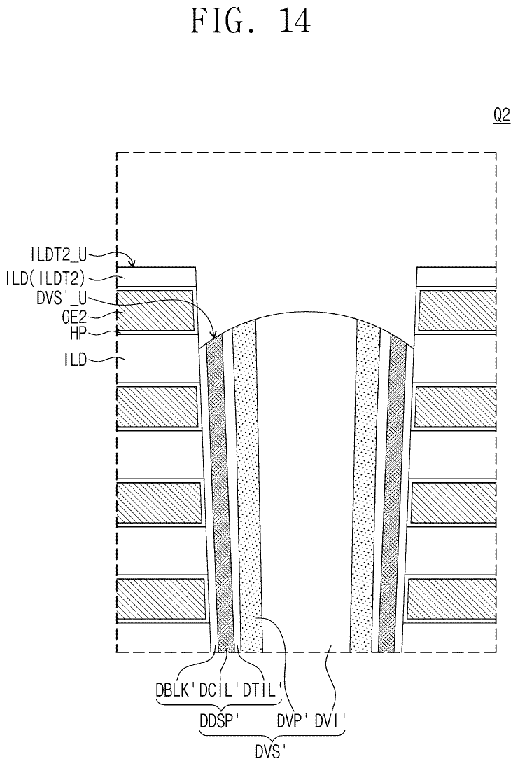

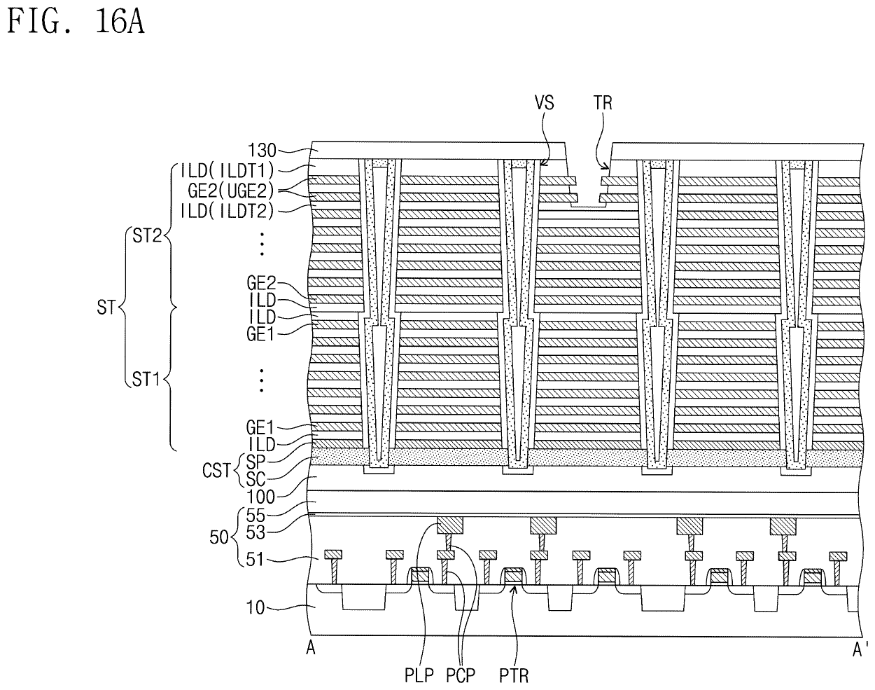

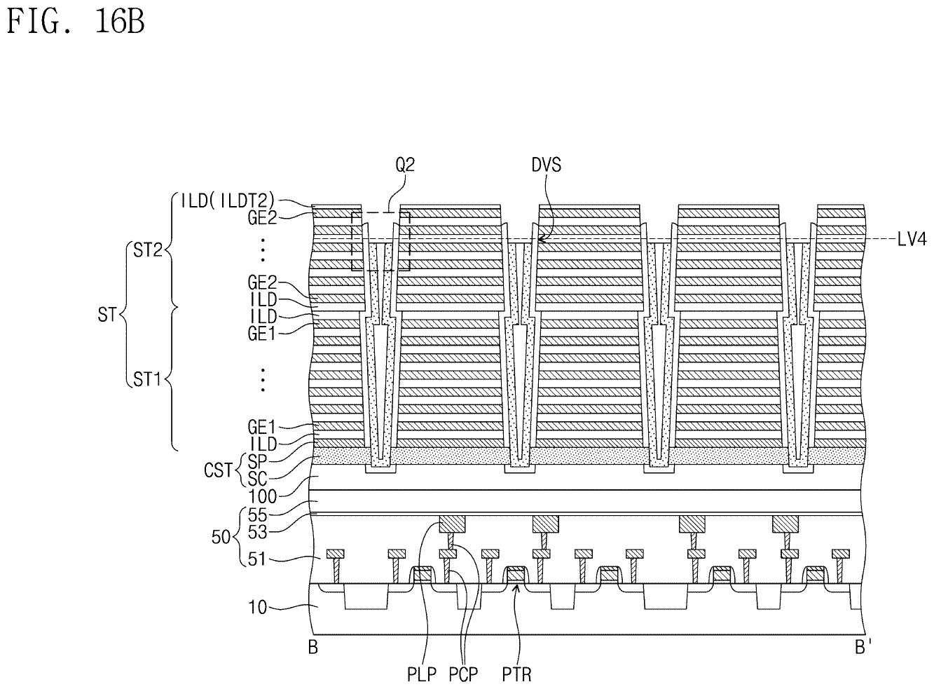

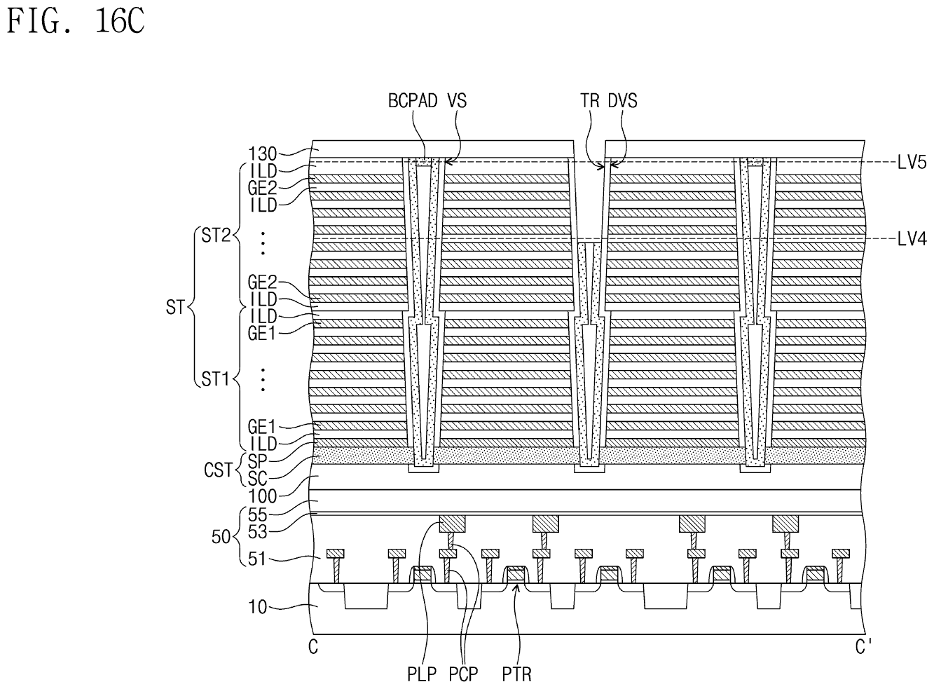

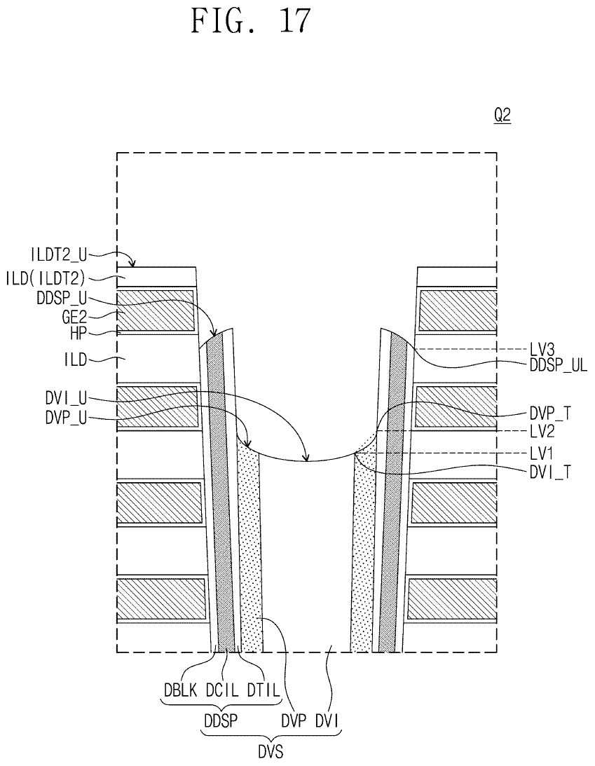

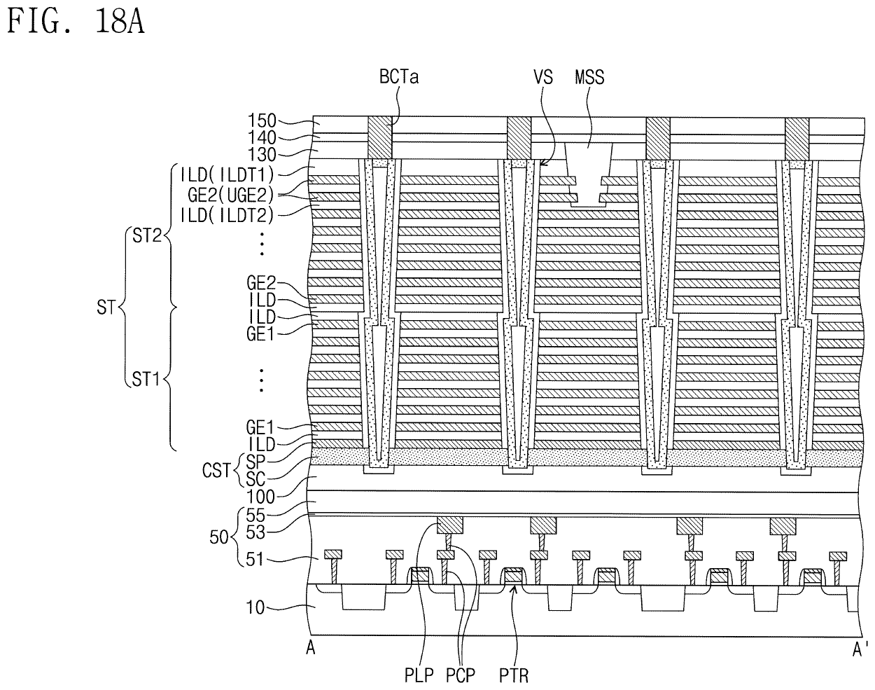

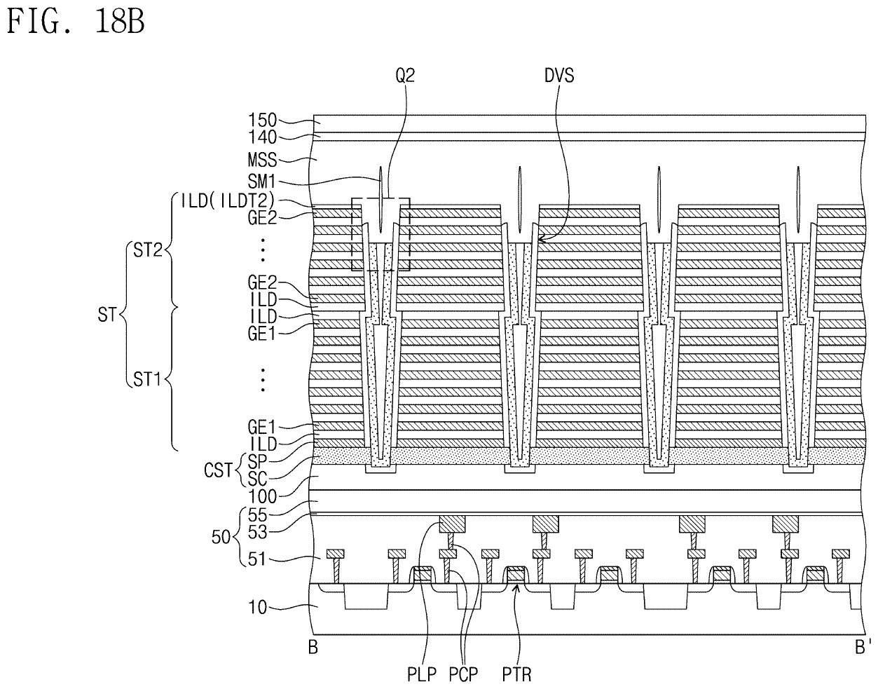

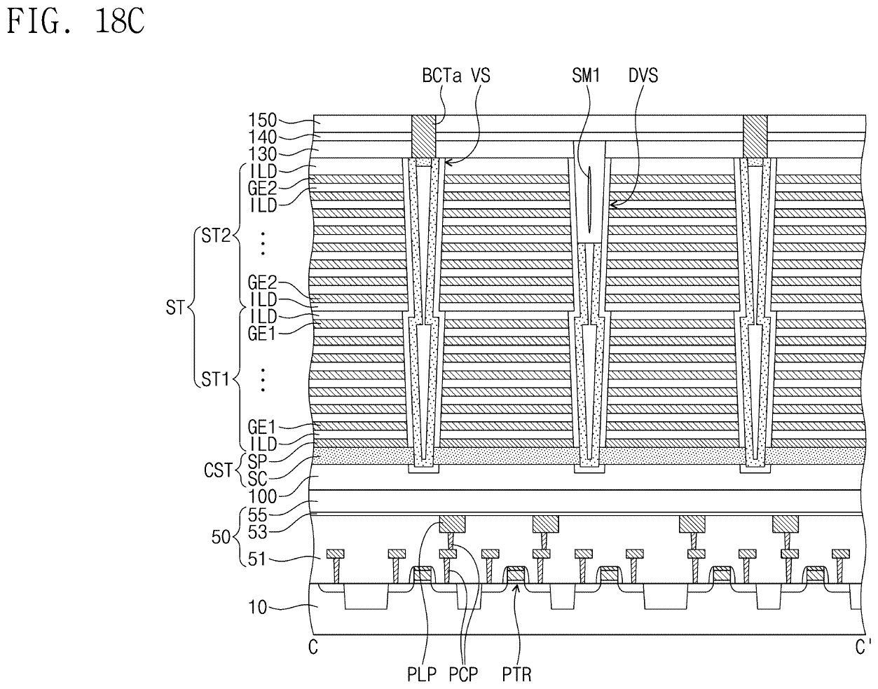

FIGS. 12 to 18C are diagrams illustrating a method of fabricating a semiconductor device according to an embodiment of the inventive concept, and here, FIGS. 12 and 15 are plan views of the semiconductor device, and FIGS. 13A to 14 and 16A to 18C are sectional or enlarged views of the semiconductor device. In detail, FIGS. 12 and 15 are plan views corresponding to the portion ‘P’ of FIG. 5. FIGS. 13A to 13C are sectional views taken along lines A-A′, B-B′, and C-C′ of FIG. 12. FIG. 14 is an enlarged sectional view illustrating a portion ‘Q2’ of FIG. 13B. FIGS. 16A to 16C are sectional views taken along lines A-A′, B-B′, and C-C′ of FIG. 15. FIG. 17 is an enlarged sectional view illustrating a portion ‘Q2’ of FIG. 16B. FIGS. 18A to 18C are sectional views corresponding to FIGS. 16A to 16C, respectively.

Referring to FIGS. 12, 13A, 13B, 13C, and 14, the peripheral circuit structure PS may be formed on the semiconductor substrate 10. The formation of the peripheral circuit structure PS may include forming the peripheral transistors PTR on the semiconductor substrate 10, forming the peripheral interconnection structures PCP and PLP on the peripheral transistors PTR, and forming the lower insulating layer 50 on the semiconductor substrate 10. The formation of the peripheral transistors PTR may include forming a device isolation layer in the semiconductor substrate 10 to define active regions, forming a gate insulating layer and a gate electrode on the active regions, and injecting impurities into the active regions to form source/drain region. The formation of the lower insulating layer 50 may include forming an insulating layer to cover the peripheral transistors PTR and the peripheral interconnection structures PCP and PLP and performing a planarization process on a top surface of the insulating layer.

The semiconductor layer 100 and the source structure CST may be sequentially formed on the lower insulating layer 50. A mold structure, in which insulating patterns and sacrificial layers are alternately stacked, may be formed on the source structure CST. Channel holes may be formed to penetrate the mold structure, and then, the vertical structures VS may be formed by sequentially forming the data storage pattern DSP, the vertical semiconductor pattern VP, and the gapfill insulating pattern VI in the channel holes. The first interlayer insulating layer 130 may be formed on the mold structure to cover the vertical structures VS. A separation trench may be formed to penetrate the mold structure, and then, the sacrificial layers may be selectively etched to form empty spaces. The electrode structure ST may be formed by forming the electrodes GE1 and GE2 to fill the empty spaces. Next, the separation structures SS1 and SS2 of FIG. 6B may be formed to fill the separation trench.

Next, a patterning process may be performed on the first interlayer insulating layer 130 to form a trench TR. The trench TR may be formed to have a shape that is recessed from the top surface of the first interlayer insulating layer 130 toward the semiconductor substrate 10. For example, the trench TR may be a line-shaped region, which is extended in the first direction D1. The trench TR may penetrate the upper electrodes UGE2 and the upper insulating layers ILDT1 and ILDT2 of the electrode structure ST and the first interlayer insulating layer 130. The upper electrodes UGE2 may be spaced apart from each other by the trench TR, and a top surface of the upper insulating layer ILDT2 may be exposed to the outside. The top surfaces of the vertical structures VS, which are overlapped with the trench TR and are arranged in the first direction D1, may also be deformed. For example, the bit line conductive pad, an upper portion of the data storage pattern, an upper portion of the vertical semiconductor pattern, and an upper portion of the gapfill insulating pattern, which are included in the vertical structure VS, may be etched to form a preliminary dummy vertical structure DVS′, which includes a preliminary dummy data storage pattern DDSP′, a preliminary dummy vertical semiconductor pattern DVP′, and a preliminary dummy gapfill insulating pattern DVI′.

A top surface DVS′_U of the preliminary dummy vertical structure DVS′ may have a convex shape and may be located at a level that is lower than a top surface ILTD2_U of the upper insulating layer ILDT2 adjacent thereto. The preliminary dummy vertical structure DVS′ may include the preliminary dummy data storage pattern DDSP′, the preliminary dummy vertical semiconductor pattern DVP′, and the preliminary dummy gapfill insulating pattern DVI′.

Next, referring to FIGS. 15, 16A, 16B, 16C, and 17, a wet etching process may be performed on the preliminary dummy gapfill insulating pattern DVI′. The wet etching process may be performed using hydrofluoric acid (HF) solution, which contains a high concentration of hydrofluoric acid (HF). As a result of the wet etching process, the dummy gapfill insulating pattern DVI may have a recessed top surface, and the recessed top surface DVI_U of the dummy gapfill insulating pattern DVI may be located at a level lower than the top surface DDSP_U of the dummy data storage pattern DDSP. Furthermore, since the dummy gapfill insulating pattern DVI is etched, a side surface of the preliminary dummy vertical semiconductor pattern DVP′ may be exposed to the outside. During the wet etching process, the upper insulating layers ILDT1 and ILDT2 exposed through the trench TR may be etched. Thus, top and bottom surfaces of the upper electrodes UGE2 may be exposed to the outside, and the trench TR may also be laterally enlarged. Furthermore, as a result of the wet etching process, the trench TR may have a shape whose width gradually decreases in a downward direction. In other words, a width, in the second direction D2, of the trench TR overlapped with the vertical structure may gradually decrease as a distance to the semiconductor layer 100 decreases in the third direction D3. For example, referring to FIGS. 15 and 16C, the trench TR may have a planar shape, which is depicted by the dotted line TR(LV4) of FIG. 15, at a fourth level LV4 and may have a planar shape, which is depicted by the solid line TR(LV5) of FIG. 15, at a fifth level LV5. The fourth level LV4 may be a vertical level, which is located between the second and third levels LV2 and LV3 of FIG. 17, and the fifth level LV5 may be a vertical level, which is higher than the third level LV3 and is equal to a vertical level of the bit line conductive pad BCPAD. A level of a top surface of the dummy gapfill insulating pattern DVI, which is vertically overlapped with the trench TR, may be lowered, as a result of the wet etching process. The dummy gapfill insulating pattern DVI may have a recessed top surface.

Next, an etching process may be performed on the preliminary dummy vertical semiconductor pattern DVP′. In an embodiment, the etching process may include a wet cleaning step which is performed through an ammonium hydroxide DIW mixture (ADM) process. As a result of the etching process, the dummy vertical semiconductor pattern DVP may be formed, and here, the uppermost portion DVP_T of the dummy vertical semiconductor pattern DVP may be located at a level, which is higher than the uppermost portion DVI_T of the dummy gapfill insulating pattern DVI, and may be in contact with the side surface of the dummy data storage pattern DDSP.

As an example, in the case where the top surface DVS′_U of the preliminary dummy vertical structure DVS′ has the profile shown in FIG. 14, the etching process should be performed to remove an upper portion of the preliminary dummy vertical semiconductor pattern DVP. The etching process would be performed through the exposed top surface of the preliminary dummy vertical semiconductor pattern DVP′ but the area of the exposed top surface is too small for the etching process to be performed normally. However, according to an embodiment of the inventive concept, as a result of the afore-described wet etching process when forming the dummy gapfill insulating pattern DVI, the side surface of the preliminary insulating pattern DVI, and thus, the etching process on the preliminary dummy vertical semiconductor pattern DVP′ may be easily performed to remove the upper portion of the preliminary dummy vertical semiconductor pattern.

Furthermore, in the case where the top surface of the dummy vertical semiconductor pattern DVP is tangent with the convex top surface of the dummy data storage pattern DDSP, like the preliminary dummy vertical semiconductor pattern DVP′ of FIG. 14, or the uppermost portion DVP_T of the dummy vertical semiconductor pattern DVP is located at a level higher than a portion of the top surface DDSP_U of the dummy data storage pattern DDSP, only the middle separation structure MSS may be disposed between the dummy vertical semiconductor pattern DVP and the electrode GE2, which are horizontally spaced apart from each other and are located at the same level. Since the middle separation structure MSS is a worse insulator than the dummy data storage pattern DDSP, a breakdown voltage between the dummy vertical semiconductor pattern DVP and the electrode GE2, which are horizontally spaced apart from each other, may be lowered or dropped.

In the fabrication process according to an embodiment of the inventive concept, the dummy gapfill insulating pattern DVI and the dummy vertical semiconductor pattern DVP may be etched in an over-etching manner. Thus, as shown in FIG. 17, the uppermost portion DVP_T of the dummy vertical semiconductor pattern DVP may be located at a level lower than the lowermost portion DDSP_UL of the top surface DDSP_U of the dummy data storage pattern DDSP, and the dummy data storage pattern DDSP may be provided to fully enclose the side surface of the dummy vertical semiconductor pattern DVP. Thus, the dummy data storage pattern DDSP may be disposed between the dummy vertical semiconductor pattern DVP and the electrode GE2, which are horizontally spaced apart from each other and are placed at the same level, and there may be no breakdown voltage drop issue described above. Thus, it may be possible to improve the electric reliability of the semiconductor device and increase an integration density of the semiconductor device.

Referring to FIGS. 18A, 18B, and 18C, the middle separation structure MSS may be formed to fill the trench TR. The formation of the middle separation structure MSS may include performing a deposition process to form an insulating layer filling the trench TR and performing a planarization process on the insulating layer. During the deposition process of the insulating material, the first seam SM1 may be formed in the middle separation structure MSS. The middle separation structure MSS may cover the top surface of the upper insulating layer ILDT2 and the top surface of the dummy vertical structure DVS.

The second and third interlayer insulating layers 140 and 150 may be formed on the first interlayer insulating layer 130 and the middle separation structure MSS. Next, lower bit line contact plugs BCTs may be formed to penetrate the second and third interlayer insulating layers 140 and 150. The lower bit line contact plugs BCTa may be formed of or include at least one of metallic materials and/or metal nitride materials.

According to an embodiment of the inventive concept, in a dummy vertical structure, a dummy vertical semiconductor pattern and a dummy gapfill insulating pattern may be located at a level lower than a dummy data storage pattern. Thus, the dummy data storage pattern may enclose a side surface of the dummy vertical semiconductor pattern, and it may be possible to prevent a breakdown voltage drop issue from occurring between the dummy vertical semiconductor pattern and the uppermost one of electrodes.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor device, comprising:
a semiconductor substrate;
an electrode structure including electrodes and insulating layers, which are stacked on the semiconductor substrate in a vertical direction and that alternate between an electrode and an insulating layer in the vertical direction;
middle separation structures that penetrate an upper portion of the electrode structure, and horizontally separate portions of the electrodes located in the upper portion from each other;
vertical structures penetrating through the electrode structure; and
dummy vertical structures penetrating through the electrode structure and vertically overlapped with the middle separation structures,
wherein each of the dummy vertical structures comprises a dummy gapfill insulating pattern, a dummy vertical semiconductor pattern enclosing a side surface of the dummy gapfill insulating pattern, and a dummy data storage pattern enclosing a side surface of the dummy vertical semiconductor pattern, and
the uppermost portion of the dummy vertical semiconductor pattern is in contact with a side surface of the dummy data storage pattern and the uppermost portion of the dummy vertical semiconductor pattern is a portion of the dummy vertical semiconductor pattern located at a level higher than the uppermost surface of the dummy gapfill insulating pattern.

2. The semiconductor device of claim 1, wherein each of the middle separation structures have a seam and each of the seams vertically overlaps with a respective dummy gapfill insulating pattern.

3. The semiconductor device of claim 1, wherein each of the middle separation structures cover a top surface and a portion of an inner side surface of a dummy data storage pattern.

4. The semiconductor device of claim 1, wherein each of the middle separation structures is in contact with a portion of the top surfaces, a portion of the side surfaces, and a portion of the bottom surfaces of the respective electrodes located in the upper portion of the electrode structure.

5. The semiconductor device of claim 1, wherein for each of the dummy vertical structures the uppermost portion of the respective vertical semiconductor pattern is located at a level lower than the lowermost portion of a top surface of the respective dummy data storage pattern.

6. The semiconductor device of claim 1, wherein for each of the dummy vertical structures the respective dummy gapfill insulating pattern has a recessed top surface.

7. The semiconductor device of claim 6, wherein the middle separation structures cover the recessed top surface of the dummy gapfill insulating patterns.

8. The semiconductor device of claim 1, wherein each of the vertical structures comprise a vertical semiconductor pattern and a data storage pattern enclosing a side surface of the vertical semiconductor pattern, and
a top surface of the vertical semiconductor pattern and a top surface of the data storage pattern are coplanar with each other.

9. The semiconductor device of claim 8, wherein each of the vertical structures further comprises a gapfill insulating pattern located in the vertical semiconductor pattern and a bit line conductive pad in contact with a top surface of the gapfill insulating pattern, and
the uppermost surface of the dummy gapfill insulating patterns are located at a level lower than a bottom surface of the bit line conductive pads.

10. The semiconductor device of claim 9, wherein the uppermost surface of the dummy vertical semiconductor patterns are located at a level lower than the bottom surface of the bit line conductive pads.

11. The semiconductor device of claim 1, further comprising separation structures that vertically penetrate the electrode structure and are extended in a first direction,
wherein at least two of the middle separation structures are disposed between two of the separation structures that are adjacent to each other in a second direction crossing the first direction.

12. The semiconductor device of claim 11, wherein the middle separation structures are extended in the first direction, and
the middle separation structures cover a side surface of the electrode structure and a side surface of the dummy data storage patterns in a second direction perpendicular to the first direction.

13. A semiconductor device, comprising:
a semiconductor substrate;
an electrode structure including electrodes and insulating layers stacked on the semiconductor substrate in a vertical direction and that alternate between an electrode and an insulating layer in the vertical direction;
middle separation structures that penetrate through an upper portion of the electrode structure to horizontally separate portion of the electrodes located in the upper portion from each other;
vertical structures penetrating through the electrode structure, each of the vertical structures comprising a gapfill insulating pattern, a vertical semiconductor pattern enclosing a side surface of the gapfill insulating pattern, and a data storage pattern enclosing a side surface of the vertical semiconductor pattern; and
dummy vertical structures penetrating through the electrode structure and vertically overlapped with the middle separation structures,
wherein each of the dummy vertical structures comprises a dummy gapfill insulating pattern, a dummy vertical semiconductor pattern enclosing a side surface of the dummy gapfill insulating pattern, and a dummy data storage pattern enclosing a side surface of the dummy vertical semiconductor pattern,
each of the middle separation structures have a first seam vertically overlapped with a corresponding dummy gapfill insulating pattern,
each of the vertical structures have a second seam formed in the respective gapfill insulating pattern, and
a width of the first seam is larger than a width of the second seam.

14. The semiconductor device of claim 13, wherein the middle separation structures cover a top surface and a side surface of the dummy data storage patterns.

15. The semiconductor device of claim 13, wherein the middle separation structures are in contact with top surfaces, side surfaces, and bottom surfaces of the upper electrodes.

16. The semiconductor device of claim 13, wherein each of the dummy gapfill insulating patterns has a recessed top surface.

17. The semiconductor device of claim 13, further comprising separation structures, which vertically penetrate the electrode structure and are extended in a first direction,
wherein at least two of the middle separation structures are disposed between two of the separation structures, which are adjacent to each other in a second direction crossing the first direction.

18. The semiconductor device of claim 17, wherein each of the middle separation structures is extended in the first direction, and
each of the middle separation structures covers a side surface of the electrode structure and a side surface of the dummy data storage pattern in a second direction perpendicular to the first direction.

19. An electronic system, comprising:
a semiconductor device including a semiconductor substrate, an electrode structure including electrodes and insulating layers, which stacked on the semiconductor substrate in a vertical direction and that alternate between an electrode and an insulating layer in the vertical direction, middle separation structures that penetrate through an upper portion of the electrode structure to separate portions of the electrodes in the upper portion from each other, vertical structures penetrating through the electrode structure, and dummy vertical structures penetrating through the electrode structure and vertically overlapped with the middle separation structures; and
a controller electrically connected to the semiconductor device through an input/output pad and configured to control the semiconductor device,
wherein each of the dummy vertical structures comprises a dummy gapfill insulating pattern, a dummy vertical semiconductor pattern enclosing a side surface of the dummy gapfill insulating pattern, and a dummy data storage pattern enclosing a side surface of the dummy vertical semiconductor pattern, and
the uppermost portion of the dummy vertical semiconductor pattern is in contact with a side surface of the dummy data storage pattern and the uppermost portion of the dummy vertical semiconductor pattern is a portion that is located at a level higher than the uppermost surface of the dummy gapfill insulating pattern.

20. The electronic system of claim 19, wherein each of the middle separation structures have a first seam formed on a respective one of the dummy gapfill insulating patterns, each of the vertical structures have a second seam formed therein, and a width of the first seam is larger than a width of the second seam.
